(19) United States
(12) Patent Application Publication
(10) Pub. No.: US 2026/0122907 A1
(43) Pub. Date: Apr. 30, 2026

(54) FERROELECTRIC FIELD EFFECT TRANSISTOR, MEMORY DEVICE, AND NEURAL NETWORK DEVICE

(71) Applicant: Samsung Electronics Co., Ltd., Suwon-si (KR)

(72) Inventors: Sijung YOO, Suwon-si (KR); Seungdam HYUN, Suwon-si (KR); Dukhyun CHOE, Suwon-si (KR)

(73) Assignee: Samsung Electronics Co., Ltd., Suwon-si (KR)

(21) Appl. No.: 19/008,980

(22) Filed: Jan. 3, 2025

(30) Foreign Application Priority Data
Jul. 25, 2024 (KR) 10-2024-0098966

(51) Int. Cl. H10B 51/30; H10B 51/20

(52) U.S. Cl. CPC H10B 51/30; H10B 51/20

(57) ABSTRACT

A ferroelectric field effect transistor may include a channel layer, a gate electrode provided to face the channel layer, a ferroelectric layer provided between the channel layer and the gate electrode, an intermediate oxide layer provided between the channel layer and the ferroelectric layer, and a source electrode and a drain electrode electrically connected to the channel layer. The channel layer may include an oxide semiconductor material. The intermediate oxide layer may include an oxide material of a metal element having oxide formation energy greater than oxide formation energy of a metal element of the ferroelectric material of the ferroelectric layer and less than oxide formation energy of a metal element of the oxide semiconductor material of the channel layer.

### CROSS-REFERENCE TO RELATED APPLICATIONS

This application is based on and claims priority under 35 U.S.C. § 119 to Korean Patent Application Nos. 10-2024-0098966, filed on Jul. 25, 2024, in the Korean Intellectual Property Office, the disclosure of which is incorporated by reference herein in its entirety.

### BACKGROUND

### 1. Field

The disclosure relates to a ferroelectric field effect transistor, a memory device, and a neural network device.

### 2. Description of the Related Art

Ferroelectrics are materials that have ferroelectricity, which means that they maintain spontaneous polarization by aligning internal electric dipole moments even when no electric field is applied from an external electric field source. Even when a certain voltage is applied to a ferroelectric and the voltage is returned to 0 V, polarization remains semi-permanent in the ferroelectric. Research on applying these ferroelectric properties to logic devices or memory devices is ongoing. For example, in the case of a ferroelectric field effect transistor using a ferroelectric, the threshold voltage of the field effect transistor may vary depending on the direction and intensity of the polarization in the ferroelectric. Logic devices or memory devices may be implemented using threshold voltage variation characteristics of such ferroelectric field effect transistors.

### SUMMARY

Provided are a ferroelectric field effect transistor and a memory device including a channel layer including an oxide semiconductor material.

In addition, provided are a ferroelectric field effect transistor and a memory device configured to prevent and/or mitigate the potential for deterioration of a channel, including an intermediate oxide layer including a material between a channel layer and a ferroelectric layer, the material having an oxidation degree less than that of a ferroelectric material of the ferroelectric layer.

In addition, provided is a neural network device that includes the ferroelectric field effect transistor.

Additional aspects will be set forth in part in the description which follows and, in part, will be apparent from the description, or may be learned by practice of the presented embodiments of the disclosure.

According to an aspect of at least one embodiment, a ferroelectric field effect transistor may include a channel layer including an oxide semiconductor material, a source electrode and a drain electrode electrically connected to the channel layer a gate electrode facing and spaced apart from the channel layer, a ferroelectric layer between the channel layer and the gate electrode, the ferroelectric layer including a ferroelectric material, and an intermediate oxide layer between the channel layer and the ferroelectric layer. The intermediate oxide layer may include an oxide material of a metal element having oxide formation energy greater than oxide formation energy of a metal element of the ferroelectric material of the ferroelectric layer and less than oxide formation energy of a metal element of the oxide semiconductor material of the channel layer.

The intermediate oxide layer may include an oxide material having a dielectric constant of 20 or more.

For example, the ferroelectric material of the ferroelectric layer may include hafnium oxide, and the oxide semiconductor material of the channel layer may include an oxide of at least one of indium (In), gallium (Ga), zinc (Zn), tungsten (W), or tin (Sn).

For example, the intermediate oxide layer may include at least one of niobium oxide (Nb₂O₅₋ₓ), tantalum oxide (Ta₂O₅₋ₓ), or titanium oxide (TiO₂₋ₓ), which have a stoichiometrically oxygen-deficient composition. Here, x may be greater than 0 and less than or equal to 0.5.

The thickness of the intermediate oxide layer may be less than that of the channel layer.

For example, the thickness of the channel layer may be about 5 nm to about 20 nm, and the thickness of the intermediate oxide layer may be about 0.1 nm to about 2 nm.

The ferroelectric field effect transistor may further include a gate intermediate layer between the gate electrode and the ferroelectric layer, and the gate intermediate layer may include at least one amorphous dielectric material from among silicon oxide, silicon nitride, aluminum oxide, and silicon oxynitride.

The gate intermediate layer may include amorphous silicon oxynitride, the gate intermediate layer may include a first surface adjacent to the gate electrode and a second surface adjacent to the ferroelectric layer, a nitrogen concentration in the gate intermediate layer may gradually increase from the first surface toward the second surface, and an oxygen concentration in the gate intermediate layer may gradually decrease from the first surface toward the second surface.

The oxygen concentration at the first surface of the gate intermediate layer is greater by a ratio of 10% or more compared to the oxygen concentration on the second surface of the gate intermediate layer, and the nitrogen concentration at the second surface of the gate intermediate layer may be greater by a ratio of 10% or more compared to the nitrogen concentration on the first surface of the gate intermediate layer.

The silicon concentration in the gate intermediate layer may gradually increase from the first surface toward the second surface, and the silicon concentration at the second surface of the gate intermediate layer may be greater by a ratio of 10% or more compared to the concentration of silicon on the first surface of the gate intermediate layer.

A ratio of the silicon concentration to the nitrogen concentration on the first surface of the gate intermediate layer may be same as a ratio of the silicon concentration to the nitrogen concentration on the second surface of the gate intermediate layer.

The gate intermediate layer may include a first gate intermediate layer in contact with the ferroelectric layer and a second gate intermediate layer in contact with the gate electrode, the first gate intermediate layer may include amorphous silicon nitride or amorphous silicon oxynitride, and the second gate intermediate layer may include amorphous silicon oxide.

The first gate intermediate layer may include amorphous silicon oxynitride, the first gate intermediate layer may include a first surface adjacent to the gate electrode and a second surface adjacent to the ferroelectric layer, a concentration of nitrogen in the first gate intermediate layer may gradually increase from the first surface toward the second surface, and a concentration of oxygen in the first gate intermediate layer may gradually decrease from the first surface toward the second surface.

The silicon concentration in the first gate intermediate layer gradually increases from the first surface toward the second surface, and a ratio of the silicon concentration to the nitrogen concentration on the first surface of the first gate intermediate layer may be same as a ratio of the silicon concentration to the nitrogen concentration on the second surface of the first gate intermediate layer.

The channel layer may include a first surface and a second surface facing each other, the source electrode and the drain electrode may be spaced apart from each other on the first surface of the channel layer, and the gate electrode may be provided to face the second surface of the channel layer.

The channel layer may include a first surface and a second surface facing each other, the gate electrode may be provided to face the first surface of the channel layer, the source electrode and the drain electrode may be spaced apart from each other on the first surface of the channel layer, the intermediate oxide layer may be provided between the source electrode and the drain electrode on the first surface of the channel layer, the source electrode may be provided to face a first side surface of the intermediate oxide layer, and the drain electrode may be provided to face a second side surface of the intermediate oxide layer opposite to the first side surface.

The channel layer, the intermediate oxide layer, the ferroelectric layer, and the gate electrode may extend in a first direction and may be sequentially provided in a second direction perpendicular to the first direction, and the source electrode and the drain electrode may be electrically connected to respective ends of the channel layer in the first direction.

The channel layer may have a cylindrical shape, the intermediate oxide layer may surround the channel layer, the ferroelectric layer may surround the intermediate oxide layer, and the gate electrode may surround the ferroelectric layer.

According to an aspect of at least one embodiment, a memory device includes a plurality of gate electrodes and a plurality of spacers alternately stacked in a first direction, a channel layer spaced apart from the plurality of gate electrodes and the plurality of spacers in a second direction perpendicular to the first direction, the channel layer extending in the first direction and comprising an oxide semiconductor material, a ferroelectric layer between the channel layer and the plurality of gate electrodes and extending in the first direction, the ferroelectric layer including a ferroelectric material, and an intermediate oxide layer between the ferroelectric layer and the channel layer and extending in the first direction such that the intermediate oxide layer separates the ferroelectric layer from the channel layer. The intermediate oxide layer may include an oxide material of a metal element having oxide formation energy higher than oxide formation energy of a metal element of the ferroelectric material of the ferroelectric layer and less than oxide formation energy of a metal element of the oxide semiconductor material of the channel layer.

According to as aspect of at least one embodiment, a neural network device includes an array of a plurality of synapse devices, wherein each of the plurality of synapse devices includes an access transistor and a ferroelectric field effect transistor, and the ferroelectric field effect transistor includes a channel layer including an oxide semiconductor material, a source electrode and a drain electrode electrically connected to the channel layer a gate electrode facing and spaced apart from the channel layer, a ferroelectric layer between the channel layer and the gate electrode, the ferroelectric layer including a ferroelectric material, and an intermediate oxide layer between the channel layer and the ferroelectric layer. The intermediate oxide layer may include an oxide material of a metal element having oxide formation energy higher than oxide formation energy of a metal element of the ferroelectric material of the ferroelectric layer and less than oxide formation energy of a metal element of the oxide semiconductor material of the channel layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view schematically showing a structure of a ferroelectric field effect transistor according to at least one embodiment;

FIG. 2 is an Ellingham diagram illustrating an example of oxide formation energy of various elements;

FIGS. 3A and 3B illustrate the transfer of oxygen between a channel layer, an intermediate oxide layer, and a ferroelectric layer of a ferroelectric field effect transistor and the result of the transfer of oxygen, respectively;

FIG. 4 is a cross-sectional view schematically showing a structure of a ferroelectric field effect transistor according to at least one embodiment;

FIG. 5 is a graph showing an oxygen concentration gradient and a nitrogen concentration gradient in a gate intermediate layer of a ferroelectric field effect transistor;

FIG. 6 is a cross-sectional view schematically showing a structure of a ferroelectric field effect transistor according to at least one embodiment;

FIG. 7 is a cross-sectional view schematically showing a structure of a ferroelectric field effect transistor according to at least one embodiment;

FIG. 8 is a cross-sectional view schematically showing a structure of a ferroelectric field effect transistor according to at least one embodiment;

FIG. 9 is a cross-sectional view schematically showing a structure of a ferroelectric field effect transistor according to at least one embodiment;

FIG. 10 is a cross-sectional view schematically showing a structure of a ferroelectric field effect transistor according to at least one embodiment;

FIG. 11 is a cross-sectional view schematically showing a structure of a ferroelectric field effect transistor according to at least one embodiment;

FIG. 12 is a cross-sectional view schematically showing a structure of a ferroelectric field effect transistor according to at least one embodiment;

FIG. 13 is a cross-sectional view schematically showing a structure of a ferroelectric field effect transistor according to at least one embodiment;

FIGS. 14 and 15 are vertical and horizontal cross-sectional views schematically showing a structure of a ferroelectric field effect transistor according to at least one embodiment, respectively;

FIG. 16 is a cross-sectional view schematically showing a structure of a ferroelectric field effect transistor according to at least one embodiment;

FIG. 17 is a cross-sectional view schematically showing a structure of a ferroelectric field effect transistor according to at least one embodiment;

FIGS. 18 and 19 are horizontal and vertical cross-sectional views schematically showing a structure of a memory cell string of a memory device according to at least one embodiment, respectively;

FIG. 20 is a cross-sectional view schematically illustrating a structure of a memory cell string of a memory device, according to at least one embodiment;

FIG. 21 is a cross-sectional view schematically illustrating a structure of a memory cell string of a memory device, according to at least one embodiment;

FIG. 22 is a diagram illustrating an equivalent circuit of a memory device according to at least one embodiment;

FIG. 23 is a schematic circuit diagram of a neural network device according to at least one embodiment; and

FIG. 24 is a schematic block diagram showing an example configuration of an electronic device including a neural network device.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a ferroelectric field effect transistor, a memory device, and a neural network device will be described with reference to detail with reference to the accompanying drawings. In the following drawings, the same reference numerals refer to the same components, and the size of each component in the drawings may be exaggerated for clarity and convenience of description. In addition, the embodiments described below are merely exemplary and various modifications are possible from these embodiments. Additionally, when the terms “about” or “substantially” are used in this specification in connection with a numerical value and/or geometric terms, it is intended that the associated numerical value includes a manufacturing tolerance (e.g., +10%) around the stated numerical value. Further, regardless of whether numerical values and/or geometric terms are modified as “about” or “substantially,” it will be understood that these values should be construed as including a manufacturing or operational tolerance (e.g., +10%) around the stated numerical values and/or geometry. Additionally, whenever a range of values is enumerated, the range includes all values within the range as if recorded explicitly clearly, and may further include the boundaries of the range. Accordingly, the range of “X” to “Y” and/or “X or greater and Y or less” includes all values between X and Y, including X and Y. In contrast, the range of “greater than X and less than Y” includes all detectable values between X and Y excluding X and Y.

Hereinafter, terms “upper” or “top” or “lower” or “bottom” may include not only those directly above/below/left/right in contact, but also those above/below/left/right without contact. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. The singular expression includes plural expressions unless the context clearly implies otherwise. In addition, when a part “includes” a component, this means that it may further include other components, not excluding other components unless otherwise stated.

The use of the term “the” and similar indicative terms may correspond to both singular and plural. If there is no explicit description or contrary description of the order of the steps or operations constituting the method, these steps or operations may be carried out in an appropriate order and are not necessarily limited to the described order.

Further, the terms “unit”, “module” or the like mean a unit that processes at least one function or operation, which may be implemented in and/or enabled by processing circuitry such as hardware or software or implemented in a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc.

The connection or connection members of lines between the components shown in the drawings exemplarily represent functional connection and/or physical or circuit connections, and may be replaceable or represented as various additional functional connections, physical connections, or circuit connections in an actual device.

The use of all examples or exemplary terms is merely for describing a technical idea in detail and the scope is not limited to the examples or exemplary terms unless limited by the claims.

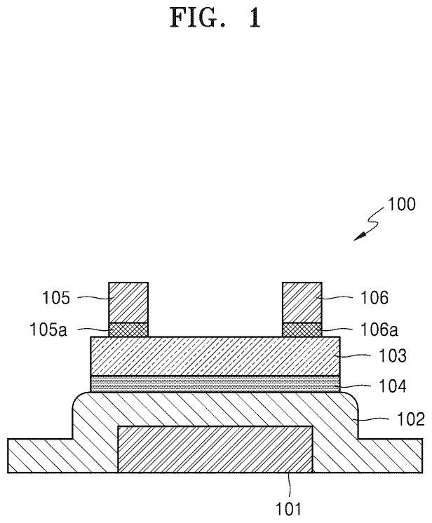

FIG. 1 is a cross-sectional view schematically showing a structure of a ferroelectric field effect transistor according to at least one embodiment. Referring to FIG. 1, a ferroelectric field effect transistor 100 according to at least one embodiment may include a gate electrode 101, a ferroelectric layer 102 surrounding both side surfaces and an upper surface of the gate electrode 101, an intermediate oxide layer 104 provided on the upper surface of the ferroelectric layer 102, a channel layer 103 provided on an upper surface of the intermediate oxide layer 104, and a source electrode 105 and a drain electrode 106 respectively provided to be electrically connected to the channel layer 103.

The ferroelectric field effect transistor 100 shown in FIG. 1 may be referred to as a lower gate structure. In other words, the source electrode 105 and the drain electrode 106 may be opposite to the gate electrode 101 with respect to the channel layer 103. For example, the source electrode 105 and the drain electrode 106 may be provided on the upper side of the channel layer 103, and the gate electrode 101 may be provided on the lower side of the channel layer 103. Therefore, the gate electrode 101 may be referred to as being provided on the lower side of the ferroelectric field effect transistor 100, and the channel layer 103 may be referred to as being provided on the upper side of the gate electrode 101 to face the gate electrode 101. The ferroelectric layer 102 may be provided between the gate electrode 101 and the channel layer 103. The intermediate oxide layer 104 may be provided between the ferroelectric layer 102 and the channel layer 103.

The source electrode 105 and the drain electrode 106 may be spaced apart from each other on the upper surface of the channel layer 103. In other words, the channel layer 103 includes a first surface (e.g., the upper surface) and a second surface (e.g., the lower surface) facing each other, the source electrode 105 and the drain electrode 106 may be provided to be spaced apart from each other on the first surface of the channel layer 103, and the gate electrode 101 may be provided facing the second surface of the channel layer 103.

In addition, the intermediate oxide layer 104 may be provided on opposite sides of the source electrode 105 and the drain electrode 106 with respect to the channel layer 103. For example, the source electrode 105 and the drain electrode 106 may be provided on the first surface (upper surface) of the channel layer 103, and the intermediate oxide layer 104 may be provided on the second surface (lower surface) of the channel layer 103. Since the ferroelectric layer 102 is provided on the lower side of the intermediate oxide layer 104, the ferroelectric layer 102 may not be in direct contact with the channel layer 103.

The ferroelectric field effect transistor 100 may also optionally further include a first contact layer 105a between the source electrode 105 and the channel layer 103 and a second contact layer 106a between the drain electrode 106 and the channel layer 103. For example, in at least some embodiments, the first contact layer 105a and the second contact layer 106a may serve to lower contact resistance between the source electrode 105 and the channel layer 103 and contact resistance between the drain electrode 106 and the channel layer 103, respectively. For example, the material of the first contact layer 105a and the second contact layer 106a may be selected to reduce the Schottky barrier between the channel layer 103 and the drain electrode 106 and/or the source electrode 105. Each of the first contact layer 105a and/or the second contact layer 106a may include, for example, indium tin oxide (ITO).

The gate electrode 101 may include conductive material including one or more of a metal, a metal nitride, a metal carbide, polysilicon, and/or combinations thereof. For example, the metals may include at least one of aluminum (Al), tungsten (W), molybdenum (Mo), titanium (Ti), or tantalum (Ta), the metal nitrides may include at least one of titanium nitride (TiN) or tantalum nitride (TaN), and the metal carbides may include at least one of aluminum or silicon doped (or containing) metal carbides, for specific example, TiAlC, TaAlC, TiSiC or TaSiC.

The gate electrode 101 may have a structure in which a plurality of materials are stacked. For example, the gate electrode 101 may have a laminated structure of a metal nitride layer/metal layer such as TiN/Al and/or a laminated structure of a metal nitride layer/metal carbide layer/metal layer such as TIN/TiAlC/W. The gate electrode 101 may include a titanium nitride (TiN) layer or molybdenum (Mo), and the example may be used in various modifications.

In addition, the gate electrode 101 may include a conductive two-dimensional material in addition to the above-described material. For example, the conductive two-dimensional material may include at least one of graphene, black phosphorus, amorphous boron nitride, two-dimensional hexagonal boron nitride (h-BN), and/or phosphorene.

The ferroelectric layer 102 may include a ferroelectric material. Ferroelectrics are materials with ferroelectric properties (that maintain spontaneous polarization by aligning internal electric dipole moments without an electric field being applied from an external electric field source). The threshold voltage of the ferroelectric field effect transistor 100 may change depending on a relative polarization direction of the ferroelectric layer 102, for example, a direction from the gate electrode 101 toward the channel layer 103 or vice versa.

The ferroelectric layer 102 may include, for example, a ferroelectric having at least one of a fluorite structure, a perovskite structure, and/or a wurtzite structure. The ferroelectric having a fluoride structure may include, for example, hafnium oxide (HfO₂) including a crystal phase lacking an inversion center (e.g., is non-centrosymmetric). For example, the hafnium oxide may be doped with at least one element of zirconium (Zr), lanthanum (La), aluminum (Al), silicon (Si), yttrium (Y), and/or gadolinium (Gd). Alternatively, the ferroelectric layer 102 may include hafnium and zirconium in substantially the same element ratio (e.g., Hf_{0.5}Zr_{0.5}O₂), and additionally, at least one element among lanthanum (La), aluminum (Al), silicon (Si), yttrium (Y), and/or gadolinium (Gd) may be doped by a ratio of less than about 10 at %. In addition, the ferroelectric having a perovskite structure may include, for example, lead zirconate titanate (PZT). The ferroelectric having a wurtzite structure may include, for example, zinc oxide (ZnO) and/or aluminum nitride (AlN). The ferroelectric of such a wurtzite structure may be doped with, for example, at least one element of boron (B) and/or scandium (Sc). The thickness of the ferroelectric layer 102 may be, for example, about 5 nanometers (nm) to about 20 (nm).

In at least some embodiments, the ferroelectric layer 102 may further include an antiferroelectric material. For example, the antiferroelectric material may include zirconium oxide. For example, the zirconium oxide may be doped with at least one element of hafnium (Hf), lanthanum (La), aluminum (Al), silicon (Si), yttrium (Y), and gadolinium (Gd).

The channel layer 103 may include an oxide semiconductor material. The oxide semiconductor material may include an oxide of, e.g., at least one of indium (In), gallium (Ga), zinc (Zn), tungsten (W), and/or tin (Sn). For example, the channel layer 103 may include at least one oxide semiconductor material from among indium-gallium-zinc oxide (IGZO), indium-zinc oxide (IZO), gallium-zinc oxide (GZO), zinc oxide (ZnO), zinc-tin oxide (ZTO), indium tungsten oxide (IWO), In₂O₃, Ga₂O₃, SnO₂, WO₃, and/or the like. In addition, the channel layer 103 may include an oxide semiconductor material further doped with at least one metal from among aluminum (Al), cadmium (Cd), copper (Cu), silicon (Si), zirconium (Zr), magnesium (Mg), and hafnium (Hf). In addition to the above-described materials, the channel layer 103 may include various other oxide semiconductor materials such as INb₂O₅, TiSrO₃, and the like.

Since the ferroelectric field effect transistor 100 uses an oxide semiconductor material as the channel layer 103, the ferroelectric field effect transistor 100 may have relatively low leakage current characteristics in an off-state and may have a relatively fast operation speed due to high electron mobility of the oxide semiconductor material. In addition, since an insulating interface layer (that causes unnecessary parasitic capacitance) is not naturally generated on the surface of the oxide semiconductor material, a memory window, which is a difference between two different threshold voltages of the ferroelectric field effect transistor 100, may increase.

However, since the ferroelectric material of the ferroelectric layer 102 is generally casily oxidized compared to the oxide semiconductor material of the channel layer 103, oxygen in the channel layer 103 may easily move to the ferroelectric layer 102 when the ferroelectric layer 102 and the channel layer 103 come into direct contact with each other. As a result, as oxygen vacancies increase in the channel layer 103, the channel layer 103 may deteriorate, and the operating characteristics of the ferroelectric field effect transistor 100 may deteriorate. For example, the leakage current may increase in the off-state of the ferroelectric field effect transistor 100. Therefore, the intermediate oxide layer 104 may be provided between the channel layer 103 and the ferroelectric layer 102 to reduce or prevent the movement of oxygen from the channel layer 103 to the ferroelectric layer 102. The intermediate oxide layer 104 may include an oxide material of a metal element having a lower oxidation degree than a metal element of a ferroelectric material of the ferroelectric material of the ferroelectric layer 102 and a higher oxidation degree than a metal element of an oxide semiconductor material of the channel layer 103.

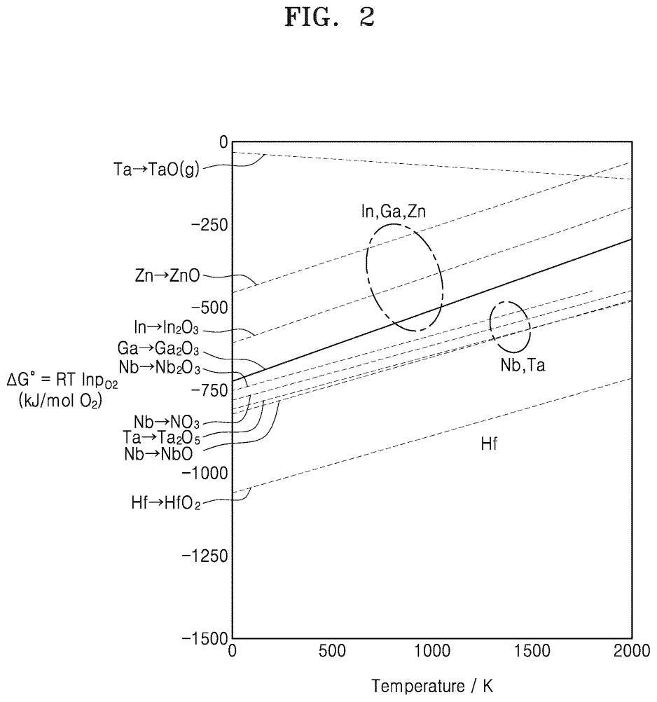

FIG. 2 is an Ellingham diagram illustrating an example of oxide formation energy of various elements. The Ellingham diagram is a graph showing free energy (i.e., oxide formation energy) for the formation of metal oxides as a function of temperature. In FIG. 2, the horizontal axis represents the temperature and the vertical axis represents the oxide formation energy. Referring to FIG. 2, hafnium (Hf) mainly used as a material of the ferroelectric layer 102 may have relatively low oxide formation energy. The low oxide formation energy of a particular element may mean that the element is easily oxidized and thus has a stable state in the oxide. In other words, a low oxide formation energy of a particular element may mean that the oxidation degree of the element is high. Although not shown in FIG. 2, zirconium (Zr), which is another possible material of the ferroelectric layer 102, may also have oxide formation energy similar to that of hafnium (Hf).

Meanwhile, indium (In), gallium (Ga), and zinc (Zn), which are mainly used as oxide semiconductor materials of the channel layer 103, may have relatively high oxide formation energy. Therefore, oxide formation energy of indium (In), gallium (Ga), and zinc (Zn) may be higher than oxide formation energy of hafnium (Hf). In other words, the degrees of oxidation of indium (In), gallium (Ga), and zinc (Zn) may be less than that of hafnium (Hf). As a result, when the ferroelectric layer 102 and the channel layer 103 are in direct contact, oxygen combined with indium (In), gallium (Ga), or zinc (Zn) in the channel layer 103 may move relatively easily to the ferroelectric layer 102.

The intermediate oxide layer 104 may include an oxide material of a metal element having oxide formation energy (or oxidation degree) between the oxide formation energy (or oxidation degree) of the metal element (or metal elements) of the ferroelectric material of the ferroelectric layer 102 (such as hafnium (Hf) and/or zirconium (Zr)), and oxide formation energy (or oxidation degree) of a metal element (or metal elements) of an oxide semiconductor material of the channel layer 103 (such as indium (In), gallium (Ga), and/or zinc (Zn)). In other words, the intermediate oxide layer 104 may include an oxide material of a metal element having oxide formation energy higher than oxide formation energy of a metal element of the ferroelectric material of the ferroelectric layer 102 and lower than oxide formation energy of a metal element of the oxide semiconductor material of the channel layer 103. Alternatively, the intermediate oxide layer 104 may include an oxide material of a metal element having an oxidation degree lower than that of the metal element of the ferroelectric material of the ferroelectric layer 102 and higher than that of the metal element of the oxide semiconductor material of the channel layer 103. The intermediate oxide layer 104 including such a material may serve to partially supply oxygen to the ferroelectric layer 102 while hardly bringing oxygen from the channel layer 103. As the intermediate oxide layer 104 is provided between the channel layer 103 and the ferroelectric layer 102, oxygen migration from the channel layer 103 to the ferroelectric layer 102 may be reduced or prevented, and as a result, deterioration of the channel layer 103 may be reduced or prevented by reducing or preventing generation of oxygen vacancies in the channel layer 103.

In addition, when the dielectric constant of the intermediate oxide layer 104 is relatively low, the electric field applied to the intermediate oxide layer 104 increases, which may reduce the electric field applied to the channel layer 103. Thus, the intermediate oxide layer 104 may include an oxide material having a relatively high dielectric constant so that voltage loss caused by the intermediate oxide layer 104 is decreased and/or minimized and an electric field may be efficiently applied to the channel layer 103. For example, the intermediate oxide layer 104 may include an oxide material having a dielectric constant of about 20 or more and/or about 25 or more.

The intermediate oxide layer 104 may include, for example, at least one of niobium oxide (Nb₂O₅), tantalum oxide (Ta₂O₅), and/or titanium oxide (TiO₂), as an oxide material that satisfies the conditions described above. Niobium oxide (Nb₂O₅) may have a dielectric constant of about 45, tantalum oxide (Ta₂O₅) may have a dielectric constant of about 25 to about 50, and titanium oxide (TiO₂) may have a dielectric constant of about 30 or more, about 60 or more, or about 80 or more, depending on a crystalline phase. In addition, referring to FIG. 2, oxide formation energy of tantalum (Ta) and niobium (Nb) may be higher than oxide formation energy of hafnium (Hf) and lower than oxide formation energy of indium (In), gallium (Ga), or zinc (Zn). In other words, the oxidation degree of tantalum (Ta) and niobium (Nb) may be lower than that of hafnium (Hf) and higher than that of indium (In), gallium (Ga), or zinc (Zn). Although not shown in FIG. 2, oxide formation energy of titanium (Ti) may also be higher than oxide formation energy of hafnium (Hf) and lower than oxide formation energy of indium (In), gallium (Ga), or zinc (Zn).

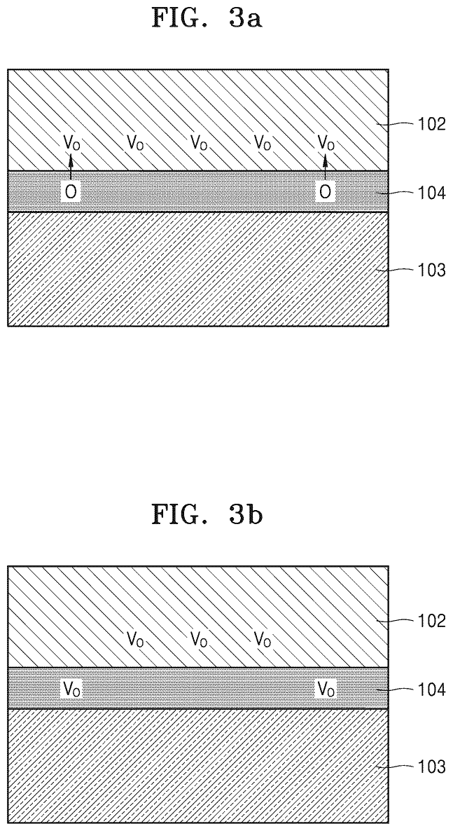

FIGS. 3A and 3B illustrate the transfer of oxygen between a channel layer 103, an intermediate oxide layer 104, and a ferroelectric layer 102 of a ferroelectric field effect transistor 100 and the result of the transfer of oxygen, respectively. Referring to FIGS. 3A and 3B, as oxygen in the intermediate oxide layer 104 partially moves to the ferroelectric layer 102, oxygen vacancies (Vo) in the ferroelectric layer 102 may be slightly reduced and oxygen vacancies (Vo) in the intermediate oxide layer 104 may be slightly increased. Since both the intermediate oxide layer 104 and the channel layer 103 include an oxide of a metal element having a relatively low oxidation degree, the amount of oxygen movement between the channel layer 103 and the intermediate oxide layer 104 may be relatively small even when the intermediate oxide layer 104 and the channel layer 103 are in direct contact with each other. Therefore, oxygen hardly moves from the channel layer 103 to the intermediate oxide layer 104. Even if oxygen partially moves from the channel layer 103 to the intermediate oxide layer 104, the amount of movement may be comparatively very small compared to the case where the channel layer 103 and the ferroelectric layer 102 directly contact each other. As a result, the formation of oxygen vacancies in the channel layer 103 may be reduced and/or prevented by providing the intermediate oxide layer 104 between the channel layer 103 and the ferroelectric layer 102.

As shown in FIG. 3B, after oxygen moves from the intermediate oxide layer 104 to the ferroelectric layer 102, the oxide of the intermediate oxide layer 104 may have a stoichiometrically oxygen-deficient composition. For example, niobium oxide may be represented by Nb₂O₅₋ₓ, tantalum oxide may be represented by Ta₂O₅₋ₓ, titanium oxide may be represented by TiO₂₋ₓ, and x may be greater than 0 and less than or equal to about 0.5 (i.e., 0<x≤0.5). Therefore, after oxygen moves from the intermediate oxide layer 104 to the ferroelectric layer 102, the final material of the intermediate oxide layer 104 may include at least one of niobium oxide (Nb₂O₅₋ₓ), tantalum oxide (Ta₂O₅₋ₓ), and titanium oxide (TiO₂₋ₓ) having a stoichiometrically oxygen-deficient composition.

A thickness of the channel layer 103 may be, for example, about 5 nm to about 20 nm. The intermediate oxide layer 104 may have a relatively small thickness to minimize (or reduce) a voltage drop caused by the intermediate oxide layer 104 so that an electric field may be efficiently applied to the channel layer 103 while having a sufficient thickness to minimize the movement of oxygen from the channel layer 103 to the ferroelectric layer 102. To this end, the thickness of the intermediate oxide layer 104 may be smaller than the thickness of the channel layer 103. For example, the thickness of the intermediate oxide layer 104 may be about 0.1 nm to about 2 nm, and/or about 0.2 nm to about 1 nm.

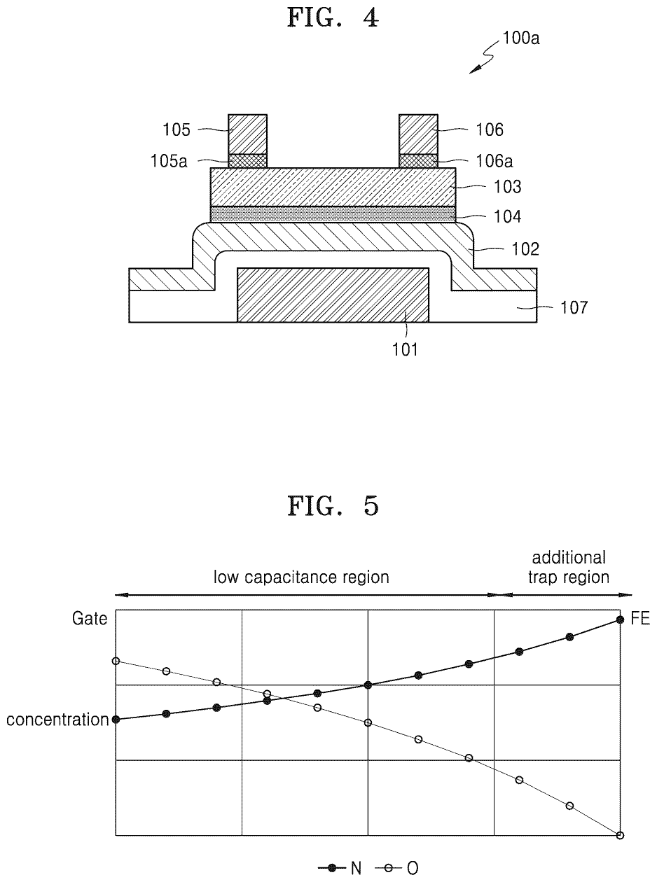

FIG. 4 is a cross-sectional view schematically showing a structure of a ferroelectric field effect transistor according to at least one embodiment. Referring to FIG. 4, a ferroelectric field effect transistor 100a according to at least one embodiment may further include a gate intermediate layer 107 provided between the gate electrode 101 and the ferroelectric layer 102. The configuration of the ferroelectric field effect transistor 100a except for the gate intermediate layer 107 is the same as and/or substantially similar to that of the ferroelectric field effect transistor 100 shown in FIG. 1, and thus, the detailed description thereof is omitted.

The memory window (MW) of the ferroelectric field effect transistor 100a may be expressed by Equation 1 below.

$$MW = \frac{Δ P - Δ {Q}_{it}}{{C}_{FE}} + \frac{Δ {Q}_{it}^{′} - Δ {Q}_{it}}{{C}_{TD}} \qquad [ Equation 1 ]$$

In Equation 1, ΔP represents the polarization amount or polarization intensity of the ferroelectric layer 102, ΔQᵢₜ represents the amount of charge trapped at the interface of the ferroelectric layer 102 facing the channel layer 103, ΔQ′ᵢₜ represents the amount of charge trapped at the interface of the ferroelectric layer 102 facing the gate electrode 101, CHE represents the capacitance of the ferroelectric layer 102, and CTD represents the capacitance between the ferroelectric layer 102 and the gate electrode 101.

As may be seen from Equation 1 above, as the capacitance between the ferroelectric layer 102 and the gate electrode 101 decreases, the memory window MW of the ferroelectric field effect transistor 100a may increase. The gate intermediate layer 107 may be provided to further increase the memory window MW of the ferroelectric field effect transistor 100a by lowering the capacitance between the ferroelectric layer 102 and the gate electrode 101. To this end, the gate intermediate layer 107 may include a dielectric material having a relatively low dielectric constant. For example, the gate intermediate layer 107 may include at least one amorphous dielectric material from among silicon oxide (SiO), silicon nitride (SIN), aluminum oxide (AlO), and silicon oxynitride (SiON). The thickness of the gate intermediate layer 107 may be about 1 nm to about 5 nm, and/or about 3 nm to about 5 nm.

When the gate intermediate layer 107 includes amorphous silicon oxynitride (SiON), the gate intermediate layer 107 may further increase the memory window by increasing the amount ΔQ′ᵢₜ of charges trapped at the interface of the ferroelectric layer 102 facing the gate electrode 101. In addition, the gate intermediate layer 107 including amorphous silicon oxynitride (SiON) may prevent, reduce, or minimize the deterioration of surrounding layers by preventing or reducing the diffusion of oxygen. To this end, the concentration of oxygen in the gate intermediate layer 107 may gradually decrease with distance towards the ferroelectric layer 102 and gradually increase with distance towards the gate electrode 101. In contrast to oxygen, the concentrations of nitrogen and silicon within the gate intermediate layer 107 may gradually increase as it approaches the ferroelectric layer 102 and gradually decrease as it approaches the gate electrode 101. Therefore, the concentration gradient of oxygen and the concentration gradients of nitrogen and silicon may appear oppositely in the gate intermediate layer 107. In other words, the gate intermediate layer 107 includes a first surface adjacent to the gate electrode 101 and a second surface adjacent to the ferroelectric layer 102, and the concentration of oxygen in the gate intermediate layer 107 may gradually decrease from the first surface toward the second surface, and the concentrations of nitrogen and silicon may gradually increase from the first surface toward the second surface.

FIG. 5 is a graph showing an oxygen concentration gradient and a nitrogen concentration gradient in a gate intermediate layer 107 of a ferroelectric field effect transistor 100a. In the graph of FIG. 5, the horizontal axis indicates the distance from the lower surface (or first surface) of the gate intermediate layer 107 facing the gate electrode 101 toward the upper surface (or second surface) of the gate intermediate layer 107 facing the ferroelectric layer 102, and the vertical axis indicates the concentrations of oxygen and nitrogen in the gate intermediate layer 107. As shown in FIG. 5, the gate intermediate layer 107 may have an oxygen concentration gradient that gradually decreases from the first surface toward the second surface. In other words, the oxygen concentration may be the highest on the first surface of the gate intermediate layer 107 adjacent to the gate electrode 101, and the oxygen concentration may gradually decrease toward the second surface of the gate intermediate layer 107 adjacent to the ferroelectric layer 102, so that the oxygen concentration may be the lowest on the second surface of the gate intermediate layer 107.

For example, compared to the oxygen concentration on the second surface of the gate intermediate layer 107, the oxygen concentration on the first surface of the gate intermediate layer 107 may be higher by a ratio of about 10% or more, about 50% or more, about 100% or more, and/or about 300% or more. The difference between the oxygen concentration on the first surface of the gate intermediate layer 107 and the oxygen concentration on the second surface of the gate intermediate layer 107 may be about 5 at % or more, about 10 at % or more, and/or about 20 at % or more. If the difference in oxygen concentrations between the first surface and the second surface of the gate intermediate layer 107 is about 5 at % or more, oxygen may be sufficiently prevented or reduced from passing through the gate intermediate layer 107, so that a maximum difference in oxygen concentrations between the upper and lower portions of the gate intermediate layer 107 does not need to be limited. However, considering the amount of oxygen that can be bonded to the gate intermediate layer 107, the difference between the oxygen concentration on the first surface of the gate intermediate layer 107 and the oxygen concentration on the second surface of the gate intermediate layer 107 may be about 60 at % or less.

In addition, the concentration of silicon (Si) and the concentration of nitrogen (N) may change according to the change in the concentration of oxygen in the gate intermediate layer 107. Referring to FIG. 5, the gate intermediate layer 107 may have a nitrogen concentration gradient that gradually increases from the first surface toward the second surface. In other words, the nitrogen concentration may be the lowest on the first surface of the gate intermediate layer 107, and the nitrogen concentration may gradually increase toward the second surface of the gate intermediate layer 107, so that the nitrogen concentration may be the maximum on the second surface of the gate intermediate layer 107. For example, compared to the nitrogen concentration on the first surface of the gate intermediate layer 107, the nitrogen concentration on the second surface of the gate intermediate layer 107 may be higher by a ratio of about 10% or more, about 20% or more, about 50% or more, and/or about 100% or more. The difference between the nitrogen concentration on the second surface of the gate intermediate layer 107 and the nitrogen concentration on the first surface of the gate intermediate layer 107 may be about 5 at % or more, about 10 at % or more, and/or about 20 at % to about 60 at %.

Although not shown in FIG. 5, like nitrogen, the silicon concentration may be the lowest on the first surface of the gate intermediate layer 107, and the silicon concentration may gradually increase toward the second surface of the gate intermediate layer 107, so that the silicon concentration may be the maximum on the second surface of the gate intermediate layer 107. For example, compared to the silicon concentration on the first surface of the gate intermediate layer 107, the silicon concentration on the second surface of the gate intermediate layer 107 may be higher by a ratio of about 10% or more, about 20% or more, about 50% or more, and/or about 100% or more. The difference between the silicon concentration on the second surface of the gate intermediate layer 107 and the silicon concentration on the first surface of the gate intermediate layer 107 may be about 5 at % or more, about 10 at % or more, or about 20 at % to about 60 at %.

A ratio of the silicon concentration to the nitrogen concentration in the gate intermediate layer 107 may be constant. In other words, in at least some embodiments, the ratio of the silicon concentration to the nitrogen concentration may not change within all regions of the gate intermediate layer 107. Therefore, the ratio of the silicon concentration to the nitrogen concentration on the first surface of the gate intermediate layer 107 may be the same as and/or substantially similar to the ratio of the silicon concentration to the nitrogen concentration on the second surface of the gate intermediate layer 107. Here, the term “the same” does not mean “the perfectly identical”, and if the deviation of the ratio of the silicon concentration to the nitrogen concentration on the first and second surfaces of the gate intermediate layer 107 is within about 5%, both parts may be considered the same.

According to the concentration gradients of elements inside the gate intermediate layer 107, the dielectric constant of the gate intermediate layer 107 may decrease due to the high oxygen concentration toward the first surface of the gate intermediate layer 107 far away from the ferroelectric layer 102, and thus the capacitance may decrease. In addition, the charge trap may increase due to the high nitrogen concentration toward the second surface of the gate intermediate layer 107 close to the ferroelectric layer 102. Therefore, a charge trap may be additionally formed in a region close to the interface with the ferroelectric layer 102, and a memory window may be further increased. In addition, oxygen and nitrogen may exist in excess of silicon in stoichiometry in the gate intermediate layer 107. Then, defects such as oxygen vacancies or nitrogen vacancies may hardly exist inside the gate intermediate layer 107.

The memory window of the ferroelectric field effect transistor 100a shown in FIG. 4 may increase as the thickness of the gate intermediate layer 107 increases, and may increase as the pulse width of a driving voltage (e.g., a program voltage or an erase voltage) increases. According to at least one embodiment, even when the thickness of the gate intermediate layer 107 is 3 nm and the pulse width of the driving voltage is 1 us which is relatively narrow, a relatively large memory window of about 10 V or more may be secured.

FIG. 6 is a cross-sectional view schematically showing a structure of a ferroelectric field effect transistor according to at least one embodiment. Referring to FIG. 6, in a ferroelectric field effect transistor 100b according to at least one embodiment, a gate intermediate layer 107 may have a multi-layered structure. For example, the gate intermediate layer 107 may include a first gate intermediate layer 107a adjacent to and/or in contact with the ferroelectric layer 102 and a second gate intermediate layer 107b adjacent to and/or in contact with the gate electrode 101. The configuration of the ferroelectric field effect transistor 100b except for the gate intermediate layer 107 is the same as and/or substantially similar to that of the ferroelectric field effect transistor 100a shown in FIG. 4, and thus, the detailed description thereof is omitted.

The first gate intermediate layer 107a may be configured to prevent, reduce, and/or minimize deterioration of surrounding layers by preventing or reducing diffusion of oxygen. The second gate intermediate layer 107b may serve to provide low capacitance. For example, the first gate intermediate layer 107a may include amorphous silicon nitride (SiN) or amorphous silicon oxynitride (SiON). The second gate intermediate layer 107b may include amorphous silicon oxide (SiO) having a relatively low dielectric constant.

When the first gate intermediate layer 107a includes amorphous silicon oxynitride (SiON), as described with reference to FIG. 5, the concentration of oxygen in the first gate intermediate layer 107a may decrease as it approaches the ferroelectric layer 102 and increase as it approaches the gate electrode 101, and the concentrations of nitrogen and silicon may increase as it approaches the ferroelectric layer 102 and decrease as it approaches the gate electrode 101. In other words, the first gate intermediate layer 107a includes a first surface adjacent to the gate electrode 101 and a second surface adjacent to the ferroelectric layer 102, and the concentration of oxygen in the first gate intermediate layer 107a may gradually decrease from the first surface toward the second surface, and the concentrations of nitrogen and silicon may gradually increase from the first surface toward the second surface. Then, the first gate intermediate layer 107a may increase the amount of electric charges trapped at the interface of the ferroelectric layer 102 to further increase the memory window.

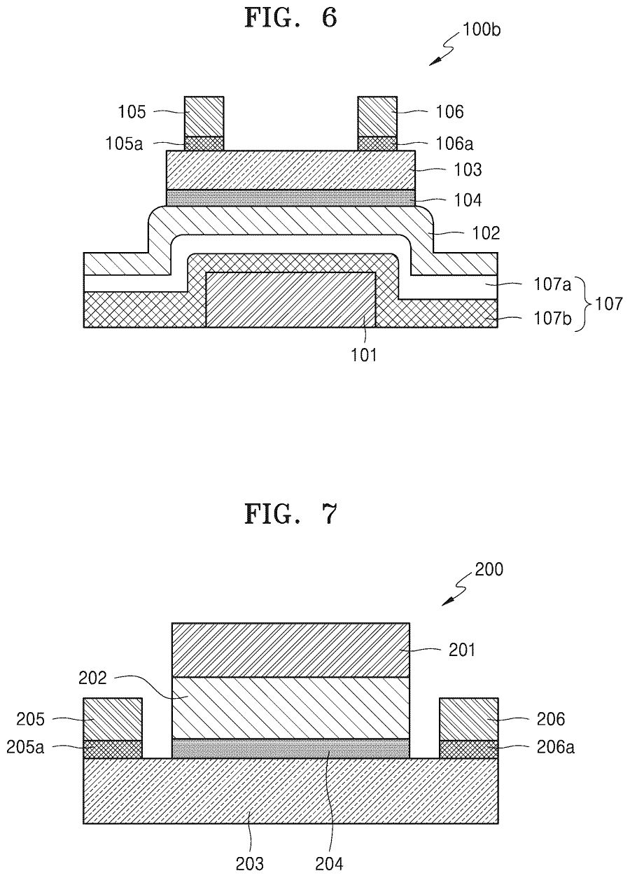

FIG. 7 is a cross-sectional view schematically showing a structure of a ferroelectric field effect transistor according to at least one embodiment. Although the lower gate structure in which the gate electrode 101 is provided below the channel layer 103 has been described so far, the ferroelectric field effect transistor according to the embodiments does not need to be limited to the lower gate structure, and may have an upper gate structure in which the gate electrode is provided above the channel layer 103. Referring to FIG. 7, a ferroelectric field effect transistor 200 may include a channel layer 203, an intermediate oxide layer 204 provided on an upper surface of the channel layer 203, a ferroelectric layer 202 provided on an upper surface of the intermediate oxide layer 204, a gate electrode 201 provided on an upper surface of the ferroelectric layer 202, and a source electrode 205 and a drain electrode 206 provided facing opposite sides of the intermediate oxide layer 204 on the upper surface of the channel layer 203. The ferroelectric field effect transistor 200 may also optionally further include a first contact layer 205a between the source electrode 205 and the channel layer 203 and a second contact layer 206a between the drain electrode 206 and the channel layer 203, as needed. Since the materials, compositions, and functions of the layers shown in FIG. 7 are the same as and/or substantially similar to the materials, compositions, and functions of the layers described with reference to FIG. 1, the detailed descriptions thereof are omitted and differences are mainly described below.

The ferroelectric field effect transistor 200 shown in FIG. 7 has an upper gate structure. In other words, the gate electrode 201 is provided on the upper side of the ferroelectric field effect transistor 200. The gate electrode 201 may be provided on the upper side of the channel layer 203 to face the channel layer 203. The ferroelectric layer 202 may be provided between the upper surface (that is, the first surface) of the channel layer 203 and the lower surface of the gate electrode 201. The intermediate oxide layer 204 may be provided between the upper surface of the channel layer 203 and the lower surface of the ferroelectric layer 202. The source electrode 205 and the drain electrode 206 may be provided on the same side as the gate electrode 201 with respect to the channel layer 203. In other words, the source electrode 205 and the drain electrode 206 may also be provided to be spaced apart from each other on the upper surface of the channel layer 203 like the gate electrode 201.

The intermediate oxide layer 204 may be provided between the source electrode 205 and the drain electrode 206 on the upper surface of the channel layer 203. The source electrode 205 and the drain electrode 206 may or may not be in direct contact with the intermediate oxide layer 204. The source electrode 205 may be provided to face a first side surface of the intermediate oxide layer 204. The drain electrode 206 may be provided to face a second side surface of the intermediate oxide layer 204 opposite to the first side surface.

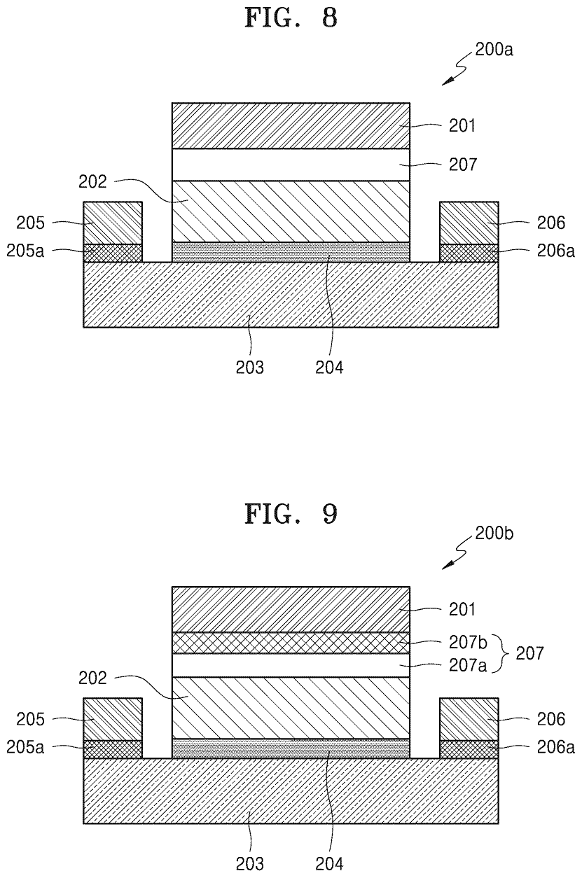

FIG. 8 is a cross-sectional view schematically showing a structure of a ferroelectric field effect transistor according to at least one embodiment. Referring to FIG. 8, a ferroelectric field effect transistor 200a may further include a gate intermediate layer 207 provided between a gate electrode 201 and a ferroelectric layer 202. The gate intermediate layer 207 may be the same as and/or substantially similar to the gate intermediate layer 107 described with reference to FIG. 4. For example, the gate intermediate layer 207 may include at least one amorphous dielectric material from among silicon oxide (SiO), silicon nitride (SIN), aluminum oxide (AlO), and silicon oxynitride (SiON). When the gate intermediate layer 207 includes amorphous silicon oxynitride (SiON), the concentration of oxygen in the gate intermediate layer 207 decreases as it gets closer to the ferroelectric layer 202 and increases as it gets closer to the gate electrode 201, and the concentrations of nitrogen and silicon may increase as it gets closer to the ferroelectric layer 202 and decrease as it gets closer to the gate electrode 201.

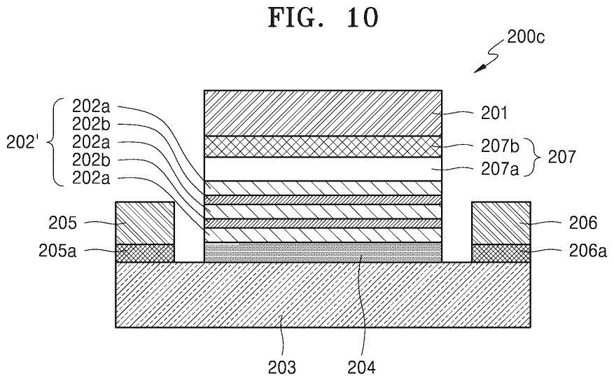

FIG. 9 is a cross-sectional view schematically showing a structure of a ferroelectric field effect transistor according to at least one embodiment. Referring to FIG. 9, in a ferroelectric field effect transistor 200b according to at least one embodiment, a gate intermediate layer 207 may have a multi-layered structure. For example, the gate intermediate layer 207 may include a first gate intermediate layer 207a adjacent to the ferroelectric layer 202 and a second gate intermediate layer 207b adjacent to the gate electrode 201. The first gate intermediate layer 207a may be the same as and/or substantially similar to the first gate intermediate layer 107a described with reference to FIG. 6, and the second gate intermediate layer 207b may be the same as the second gate intermediate layer 107b described with reference to FIG. 6. For example, the first gate intermediate layer 207a may include amorphous silicon nitride (SiN) or amorphous silicon oxynitride (SiON), and the second gate intermediate layer 207b may include amorphous silicon oxide (SiO) having a relatively low dielectric constant. When the first gate intermediate layer 207a includes amorphous silicon oxynitride (SiON), the concentration of oxygen in the first gate intermediate layer 207a decreases as it gets closer to the ferroelectric layer 202 and increases as it gets closer to the gate electrode 201, and the concentrations of nitrogen and silicon may increase as it gets closer to the ferroelectric layer 202 and decrease as it gets closer to the gate electrode 201. In other words, the first gate intermediate layer 207a includes a first surface adjacent to the gate electrode 201 and a second surface adjacent to the ferroelectric layer 202, and the concentration of oxygen in the first gate intermediate layer 207a may gradually decrease from the first surface toward the second surface, and the concentrations of nitrogen and silicon may gradually increase from the first surface toward the second surface.

FIG. 10 is a cross-sectional view schematically showing a structure of a ferroelectric field effect transistor according to at least one embodiment. Referring to FIG. 10, a ferroelectric layer 202′ of a ferroelectric field effect transistor 200c according to at least one embodiment may include a plurality of first material layers 202a and at least one second material layer 202b between two first material layers 202a facing each other. Although three first material layers 202a and two second material layers 202b are illustrated in FIG. 10, the numbers of the first material layers 202a and the second material layers 202b are not limited thereto. For example, the ferroelectric layer 202′ may include two first material layers 202a and one second material layer 202b, or the ferroelectric layer 202′ may include four first material layers 202a and three second material layers 202b. The remaining configuration of the ferroelectric field effect transistor 200c shown in FIG. 10 except for the ferroelectric layer 202′ may be the same as and/or substantially similar to the configuration of the ferroelectric field effect transistor 200b described above.

The first material layer 202a may include the ferroelectric material of the ferroelectric layer 202 described with reference to FIG. 1. For example, the first material layer 202a may include a ferroelectric having at least one of the fluorite structure, the perovskite structure, and the wurtzite structure described above. The second material layer 202b may include a paraelectric material. For example, the second material layer 202b may include at least one paraelectric of Al₂O₃, SiO₂, La₂O₃, and Y₂O₃.

In the case of the above-described ferroelectric material, when the thickness is about 10 nm or more, ferroelectric characteristics may begin to gradually deteriorate as the thickness increases. Accordingly, it is difficult to form the ferroelectric layer 102 or 202 into a single layer having a thickness of about 20 nm or more. As shown in FIG. 10, by stacking the plurality of first material layers 202a including a ferroelectric material, the ferroelectric layer 202′ may be formed to have an effective thickness of 20 nm or more without degrading ferroelectric properties. The thickness of each of the first material layers 202a may be, for example, about 5 nm to about 10 nm. In addition, the thickness of the second material layer 202b may be small enough not to deteriorate the ferroelectric characteristics of the ferroelectric layer 202′. For example, the thickness of the second material layer 202b may be about 0.1 nm to about 1 nm.

Although a ferroelectric field effect transistor having a planar channel in a horizontal direction has been described above, it is also possible to implement a ferroelectric field effect transistor having a vertical channel in a vertical direction.

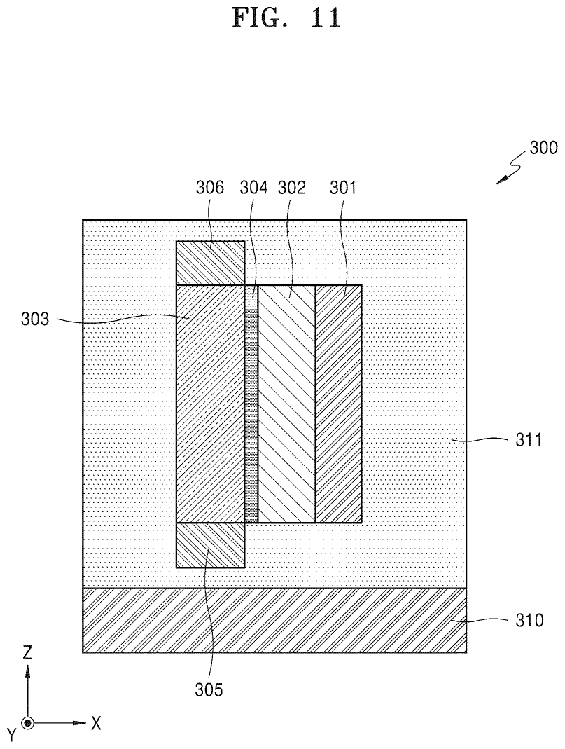

FIG. 11 is a cross-sectional view schematically showing a structure of a ferroelectric field effect transistor according to at least one embodiment. Referring to FIG. 11, a ferroelectric field effect transistor 300 according to at least one embodiment may include a source electrode 305, a channel layer 303 provided on the source electrode 305 and extending in a first direction (e.g., a vertical direction or a Z-axis direction), a drain electrode 306 provided on the channel layer 303, a gate electrode 301 provided to face one side surface of the channel layer 303 in a second direction (e.g., a horizontal direction or an X-axis direction) perpendicular to the first direction, a ferroelectric layer 302 provided between one side surface of the channel layer 303 and the gate electrode 301 in the second direction, and an intermediate oxide layer 304 provided between one side surface of the channel layer 303 and the ferroelectric layer 302 in the second direction. Although not shown in FIG. 11, a first contact layer may be further provided between the source electrode 305 and the channel layer 303 in the first direction, and a second contact layer may be further provided between the drain electrode 306 and the channel layer 303 in the first direction. Since the materials, compositions, and functions of the layers shown in FIG. 11 are the same as (and/or substantially similar to) the materials, compositions, and functions of the layers described with reference to FIG. 1, the detailed descriptions thereof are omitted and differences are mainly described below.

As shown in FIG. 11, the channel layer 303, the intermediate oxide layer 304, the ferroelectric layer 302, and the gate electrode 301 may be sequentially provided in the horizontal direction (i.e., the second direction) and extend in the vertical direction (e.g., the first direction). The source electrode 305 and the drain electrode 306 may be provided to be electrically connected to a lower portion and an upper portion or both ends of the channel layer 303 in the vertical direction. The width of the source electrode 305 and the width of the drain electrode 306 in the second direction may be the same as the width of the channel layer 303 or may be slightly less or greater than the width of the channel layer 303. Even when the width of the source electrode 305 and the width of the drain electrode 306 in the second direction are greater than the width of the channel layer 303, the widths of the source electrode 305 and the drain electrode 306 may be limited so as not to be in contact with the gate electrode 301. In addition, the channel layer 303, the intermediate oxide layer 304, the ferroelectric layer 302, and the gate electrode 301 may have the same length in the first direction, but are not limited thereto.

The ferroelectric field effect transistor 300 may further include a substrate 310, and the source electrode 305 may be provided over an upper surface of the substrate 310. The ferroelectric field effect transistor 300 may further include an interlayer insulating layer 311 provided on the substrate 310 to surround the channel layer 303, the intermediate oxide layer 304, the ferroelectric layer 302, the gate electrode 301, the source electrode 305, and the drain electrode 306. In FIG. 11, the source electrode 305 is spaced apart from the substrate 310 in the vertical direction (i.e., the first direction), and the interlayer insulating layer 311 is provided between the source electrode 305 and the substrate 310. However, when the substrate 310 is an insulating substrate, the source electrode 305 may be provided to be in direct contact with the upper surface of the substrate 310.

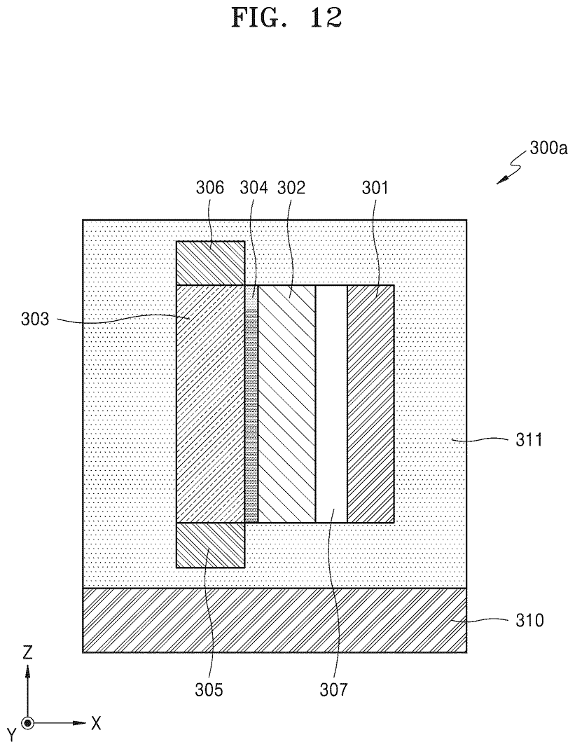

FIG. 12 is a cross-sectional view schematically showing a structure of a ferroelectric field effect transistor according to at least one embodiment. Referring to FIG. 12, a ferroelectric field effect transistor 300a may further include a gate intermediate layer 307 provided between a gate electrode 301 and a ferroelectric layer 302 in a second direction. Other configurations of the ferroelectric field effect transistor 300a may be the same as and/or substantially similar to those of the ferroelectric field effect transistor 300 shown in FIG. 11. The gate intermediate layer 307 may extend in the first direction as in other layers. The gate intermediate layer 307 may be the same as the gate intermediate layer 107 described with reference to FIG. 4. For example, the gate intermediate layer 307 may include at least one amorphous dielectric material from among silicon oxide (SiO), silicon nitride (SiN), aluminum oxide (AlO), and silicon oxynitride (SiON). When the gate intermediate layer 307 includes amorphous silicon oxynitride (SiON), the concentration of oxygen in the gate intermediate layer 307 decreases as it gets closer to the ferroelectric layer 302 and increases as it gets closer to the gate electrode 301, and the concentrations of nitrogen and silicon may increase as it gets closer to the ferroelectric layer 302 and decrease as it gets closer to the gate electrode 301.

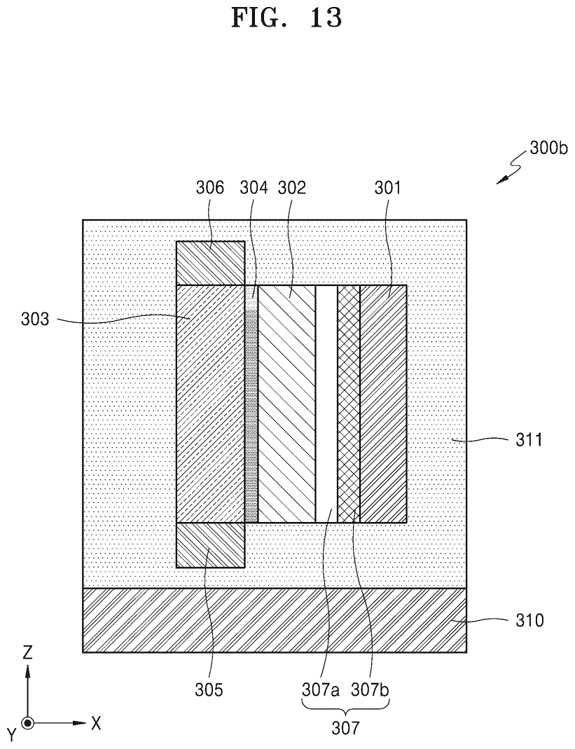

FIG. 13 is a cross-sectional view schematically showing a structure of a ferroelectric field effect transistor according to at least one embodiment; Referring to FIG. 13, the gate intermediate layer 307 of the ferroelectric field effect transistor 300b according to at least one embodiment may include a first gate intermediate layer 307a adjacent to the ferroelectric layer 302 in the second direction and a second gate intermediate layer 307b adjacent to the gate electrode 301 in the second direction. The first gate intermediate layer 307a and the second gate intermediate layer 307b may extend in the first direction. The first gate intermediate layer 307a may be the same as the first gate intermediate layer 107a described with reference to FIG. 6, and the second gate intermediate layer 307b may be the same as and/or substantially similar to the second gate intermediate layer 107b described with reference to FIG. 6. For example, the first gate intermediate layer 307a may include amorphous silicon nitride (SiN) or amorphous silicon oxynitride (SiON), and the second gate intermediate layer 307b may include amorphous silicon oxide (SiO) having a relatively low dielectric constant. When the first gate intermediate layer 307a includes amorphous silicon oxynitride (SiON), the concentration of oxygen in the first gate intermediate layer 307a decreases as it gets closer to the ferroelectric layer 302 and increases as it gets closer to the gate electrode 301, and the concentrations of nitrogen and silicon may increase as it gets closer to the ferroelectric layer 302 and decrease as it gets closer to the gate electrode 301.

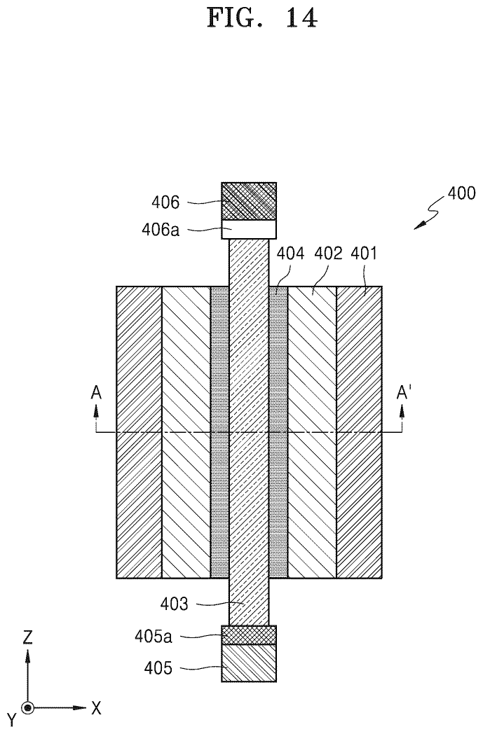

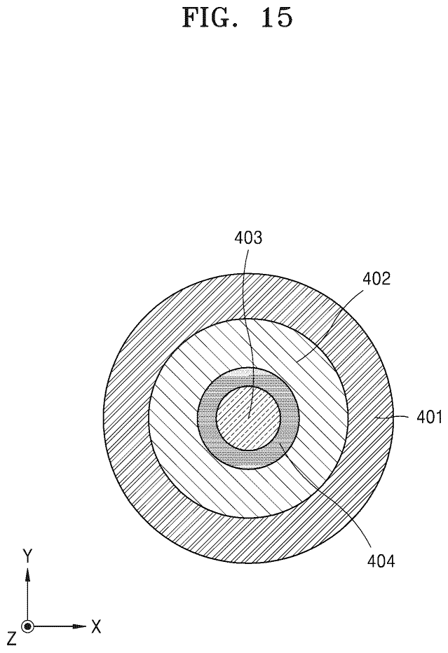

Although the ferroelectric field effect transistors of the vertical channel structure shown in FIGS. 11 to 13 include a plurality of flat plate-shaped layers extending in the vertical direction and arranged in the horizontal direction, a plurality of layers may be arranged in a concentric form. FIGS. 14 and 15 are vertical and horizontal cross-sectional views schematically showing a structure of a ferroelectric field effect transistor according to at least one embodiment, respectively. FIG. 15 is a schematic view taken along line A-A′ of FIG. 14. Referring to FIGS. 14 and 15, the ferroelectric field effect transistor 400 may include a channel layer 403 having a cylindrical shape extending in the vertical direction or a first direction (Z-axis direction), an intermediate oxide layer 404 surrounding the channel layer 403, a ferroelectric layer 402 surrounding the intermediate oxide layer 404, and a gate electrode 401 surrounding the ferroelectric layer 402. The channel layer 403, the intermediate oxide layer 404, the ferroelectric layer 402, and the gate electrode 401 may extend in the vertical direction or a first direction (Z-axis direction) and may be arranged in a concentric form. The materials, compositions, and functions of the layers illustrated in FIGS. 14 and 15 are the same as (and/or substantially similar to) the materials, compositions, and functions of the layers described in FIG. 11, and thus a detailed description thereof is omitted.

The ferroelectric field effect transistor 400 may also include a source electrode 405 provided on a lower surface of the channel layer 403 and a drain electrode 406 provided on an upper surface of the channel layer 403. In other words, the source electrode 405 and the drain electrode 406 may be provided at both ends of the channel layer 403 in the first direction, respectively. In addition, the ferroelectric field effect transistor 400 may further include a first contact layer 405a provided between the channel layer 403 and the source electrode 405, and a second contact layer 406a provided between the channel layer 403 and the drain electrode 406.

The channel layer 403 may further protrude in the first direction with respect to other layers, that is, the intermediate oxide layer 404, the ferroelectric layer 402, and the gate electrode 401. In other words, the length of the channel layer 403 in the first direction may be greater than the lengths of the intermediate oxide layer 404, the ferroelectric layer 402, and the gate electrode 401 in the first direction. Although not shown in FIGS. 11 to 13, even in FIGS. 11 to 13, the length of the channel layer 303 may be greater than the lengths of other layers. In this case, the widths of the source electrode 405 and the drain electrode 406 in the second direction may not be limited. Alternatively, in the case of FIGS. 14 and 15, the length of the channel layer 403 in the first direction may be the same as the lengths of the intermediate oxide layer 404, the ferroelectric layer 402, and the gate electrode 401 in the first direction. In this case, widths of the source electrode 405 and the drain electrode 406 in the second direction may be limited such that the source electrode 405 and the drain electrode 406 are not in contact with the gate electrode 401.

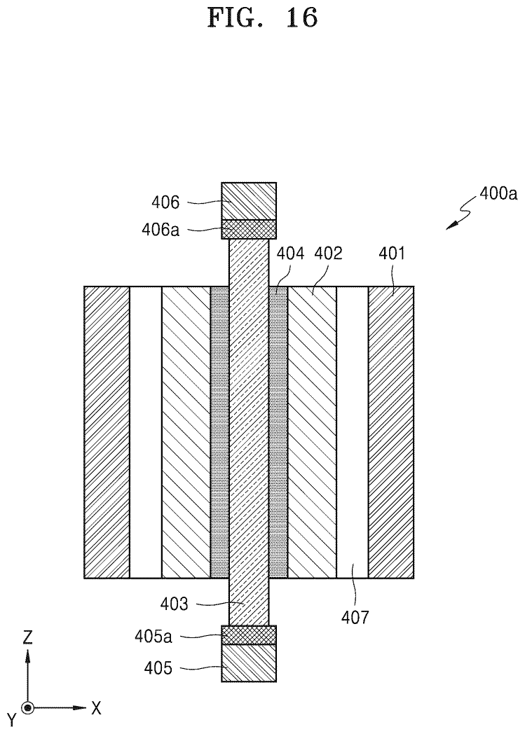

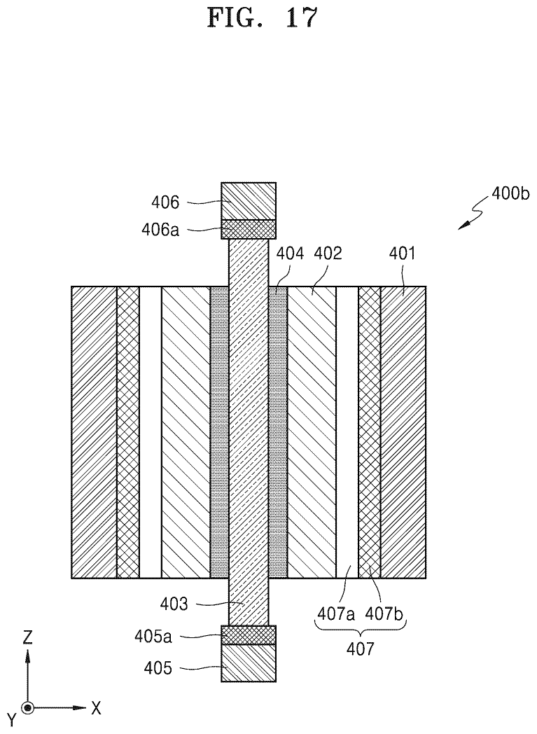

FIG. 16 is a cross-sectional view schematically showing a structure of a ferroelectric field effect transistor according to at least one embodiment. Referring to FIG. 16, a ferroelectric field effect transistor 400a may further include a gate intermediate layer 407 provided between a gate electrode 401 and a ferroelectric layer 402 in a second direction. Other configurations of the ferroelectric field effect transistor 400a may be the same as those of the ferroelectric field effect transistor 400 shown in FIGS. 14 and 15. The gate intermediate layer 407 may extend in the first direction as in other layers. The gate intermediate layer 407 may surround the ferroelectric layer 402, and the gate electrode 401 may surround the gate intermediate layer 407. The gate intermediate layer 407 may include the same material (or a substantially similar material) as the gate intermediate layer 107 described with reference to FIG. 4.

FIG. 17 is a cross-sectional view schematically showing a structure of a ferroelectric field effect transistor according to at least one embodiment. Referring to FIG. 17, the gate intermediate layer 407 of the ferroelectric field effect transistor 400b according to at least one embodiment may include a first gate intermediate layer 407a adjacent to the ferroelectric layer 402 in the second direction and a second gate intermediate layer 407b adjacent to the gate electrode 401 in the second direction. The first gate intermediate layer 407a and the second gate intermediate layer 407b may extend in the first direction. The first gate intermediate layer 407a may surround the ferroelectric layer 402, the second gate intermediate layer 407b may surround the first gate intermediate layer 407a, and the gate electrode 401 may surround the second gate intermediate layer 407b. The first gate intermediate layer 407a may include the same material as the first gate intermediate layer 107a described with reference to FIG. 6, and the second gate intermediate layer 407b may include the same material (or a substantially similar material) as the second gate intermediate layer 107b described with reference to FIG. 6.

The configuration including the oxide semiconductor channel layer, the intermediate oxide layer, and the ferroelectric layer described above may be applied to a memory device having a vertical NAND (VNAND) architecture, which is a three-dimensional (or vertical) NAND (in which NAND is an abbreviation of NOT-AND).

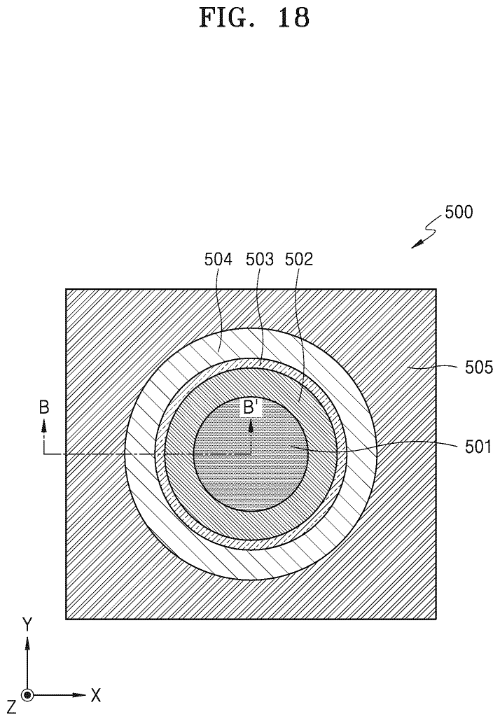

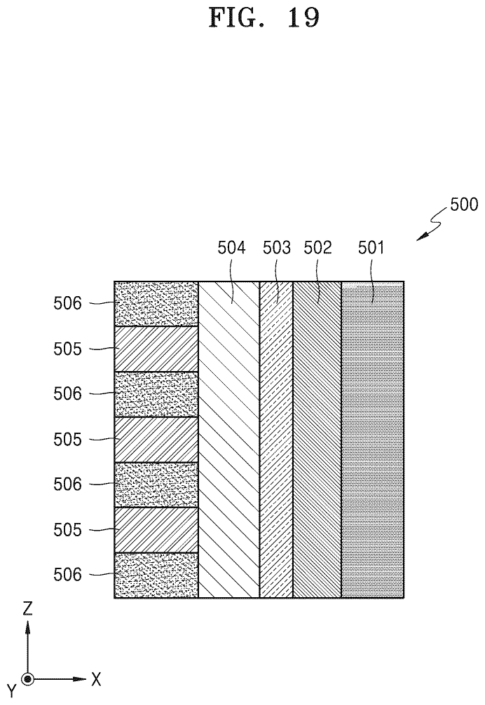

FIGS. 18 and 19 are horizontal and vertical cross-sectional views schematically showing a structure of a memory cell string of a memory device according to at least one embodiment, respectively. Referring to FIG. 18, a memory cell string 500 of a memory device according to at least one embodiment may include a central filling material 501, a channel layer 502, an intermediate oxide layer 503, a ferroelectric layer 504, and a gate electrode 505, which are concentrically arranged on an XY plane. For example, the channel layer 502 may be provided to surround the cylindrical central filling material 501, the intermediate oxide layer 503 may be provided to surround the channel layer 502, the ferroelectric layer 504 may be provided to surround the intermediate oxide layer 503, and the gate electrode 505 may be provided to surround the ferroelectric layer 504. The central filling material 501 may serve to support the channel layer 502 and the memory cell string 500 by filling a space on the inner wall side of the channel layer 502. However, the central filling material 501 is not an essential component and may be omitted. In this case, an empty space may exist instead of the central filling material 501.

FIG. 19 schematically shows a structure of a memory cell string 500 taken in a first direction (i.e., the Z-axis direction) from the center of the central filling material 501 to the gate electrode 505 along the line B-B′ in FIG. 18. Referring to FIG. 19, the memory cell string 500 may include a plurality of gate electrodes 505 and a plurality of spacers 506 alternately provided in the first direction, a channel layer 502 that faces and is spaced apart from the plurality of gate electrodes 505 and the plurality of spacers 506 in a second direction (i.e., the X-axis direction) and continuously extends in the first direction, a ferroelectric layer 504 that continuously extends in the first direction and provided between the channel layer 502 and the plurality of gate electrodes 505, and an intermediate oxide layer 503 continuously extending in the first direction and provided between the ferroelectric layer 504 and the channel layer 502. In addition, the memory cell string 500 may further include a central filling material 501 continuously extending in the first direction inside the channel layer 502. In other words, the ferroelectric layer 504, the intermediate oxide layer 503, the channel layer 502, and the central filling material 501 may be sequentially provided in the second direction from the plurality of gate electrodes 505 and the plurality of spacers 506.

Each of the plurality of spacers 506 may include silicon oxide (SiO₂) having insulating properties, but is not limited thereto. The ferroelectric layer 504 may include the same ferroelectric material as the ferroelectric layer 102 described with reference to FIG. 1, the channel layer 502 may include the same oxide semiconductor material as the channel layer 103 described with reference to FIG. 1, and the intermediate oxide layer 503 may include the same (or a substantially similar) oxide material as the intermediate oxide layer 104 described with reference to FIG. 1. In other words, the intermediate oxide layer 503 may include an oxide material of a metal element having a lower oxidation degree than a metal element of a ferroelectric material of the ferroelectric material of the ferroelectric layer 504 and a higher oxidation degree than a metal element of an oxide semiconductor material of the channel layer 502. For example, the intermediate oxide layer 503 may include at least one material from among niobium oxide (Nb₂O₅₋ₓ), tantalum oxide (Ta₂O₅₋ₓ), and titanium oxide (TiO₂₋ₓ), which have a stoichiometrically oxygen-deficient composition, where x is greater than 0 and less than or equal to about 0.5 (i.e., 0<x≤0.5).

Although not shown, a source electrode and a drain electrode may be electrically connected to both ends of the channel layer 502 in the first direction. For example, a source electrode may be provided at a lower side of the channel layer 502, and a drain electrode may be provided at an upper side of the channel layer 502.

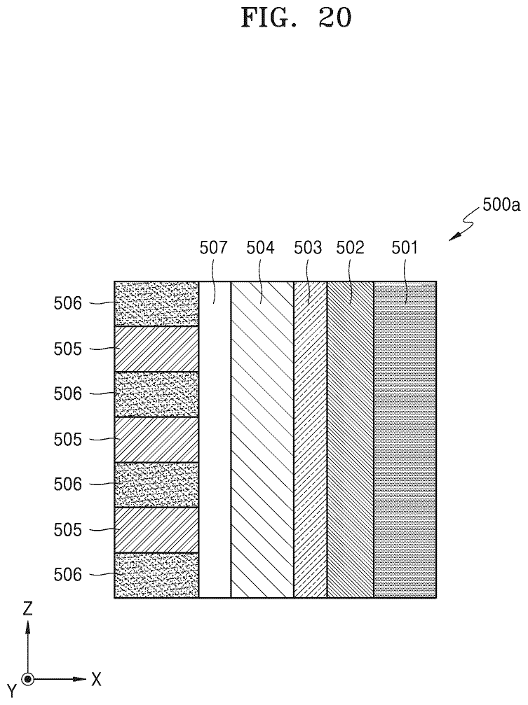

FIG. 20 is a cross-sectional view schematically illustrating a structure of a memory cell string of a memory device, according to at least one embodiment. Referring to FIG. 20, a memory cell string 500a may further include a gate intermediate layer 507 continuously extending in a first direction and provided between a plurality of gate electrodes 505 and a ferroelectric layer 504. Since the configuration of the memory cell string 500a excluding the gate intermediate layer 507 is the same as (or substantially similar to) the configuration of the memory cell string 500 shown in FIGS. 18 and 19, a detailed description thereof is omitted.

The gate intermediate layer 507 may be the same as (or substantially similar to) the gate intermediate layer 107 described with reference to FIG. 4. For example, the gate intermediate layer 507 may include at least one amorphous dielectric material from among silicon oxide (SiO), silicon nitride (SiN), aluminum oxide (AO), and silicon oxynitride (SiON). In addition, when the gate intermediate layer 507 includes amorphous silicon oxynitride (SiON), the concentration of oxygen in the gate intermediate layer 507 decreases as it gets closer to the ferroelectric layer 504 and increases as it gets closer to the gate electrode 505, and the concentrations of nitrogen and silicon may increase as it gets closer to the ferroelectric layer 504 and decrease as it gets closer to the gate electrode 505. In other words, the gate intermediate layer 507 includes a first surface adjacent to the gate electrode 505 and a second surface adjacent to the ferroelectric layer 504, and the concentration of oxygen in the gate intermediate layer 507 may gradually decrease from the first surface toward the second surface, and the concentrations of nitrogen and silicon may gradually increase from the first surface toward the second surface.

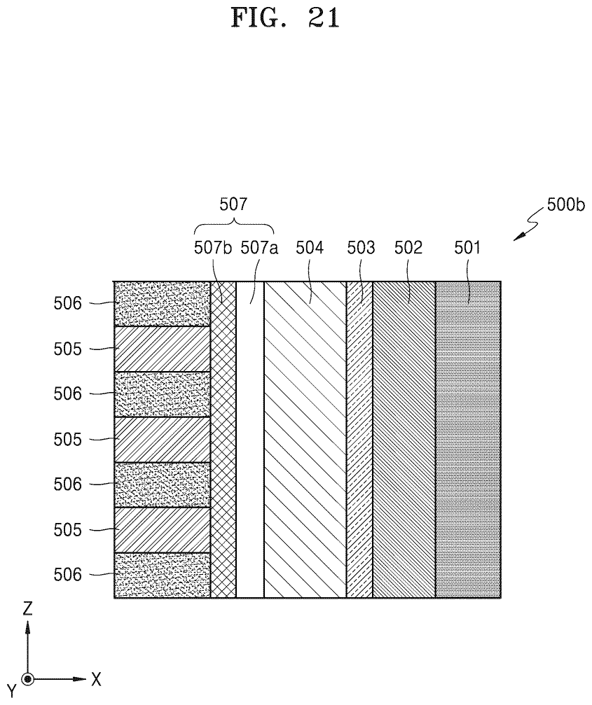

FIG. 21 is a cross-sectional view schematically illustrating a structure of a memory cell string of a memory device, according to at least one embodiment. Referring to FIG. 21, in the memory cell string 500b according to at least one embodiment, the gate intermediate layer 507 may have a multi-layered structure. For example, the gate intermediate layer 507 may include a first gate intermediate layer 507a adjacent to the ferroelectric layer 504 and a second gate intermediate layer 507b adjacent to the gate electrode 505. The first gate intermediate layer 507a may be the same as the first gate intermediate layer 107a described with reference to FIG. 6, and the second gate intermediate layer 507b may be the same as the second gate intermediate layer 107b described with reference to FIG. 6. For example, the first gate intermediate layer 507a may include amorphous silicon nitride (SiN) or amorphous silicon oxynitride (SiON), and the second gate intermediate layer 507b may include amorphous silicon oxide (SiO) having a relatively low dielectric constant. When the first gate intermediate layer 507a includes amorphous silicon oxynitride (SiON), the concentration of oxygen in the first gate intermediate layer 507a decreases as it gets closer to the ferroelectric layer 504 and increases as it gets closer to the gate electrode 505, and the concentrations of nitrogen and silicon may increase as it gets closer to the ferroelectric layer 504 and decrease as it gets closer to the gate electrode 505. In other words, the first gate intermediate layer 507a includes a first surface adjacent to the gate electrode 505 and a second surface adjacent to the ferroelectric layer 504, and the concentration of oxygen in the first gate intermediate layer 507a may gradually decrease from the first surface toward the second surface, and the concentrations of nitrogen and silicon may gradually increase from the first surface toward the second surface.

Within the memory cell strings 500, 500a, and 500b shown in FIGS. 18 to 21, the gate electrode 505, a portion of the gate intermediate layer 507 adjacent to the gate electrode 505, in the second direction, a portion of the ferroelectric layer 504, a portion of the intermediate oxide layer 503, and a portion of the channel layer 502 may form one memory cell. In this matter, it may be considered that the memory cell strings 500, 500a, and 500b include a plurality of memory cells stacked in the first direction. In addition, a memory device having a VNAND structure may include the plurality of memory cell strings 500, 500a, and 500b provided in two dimensions.

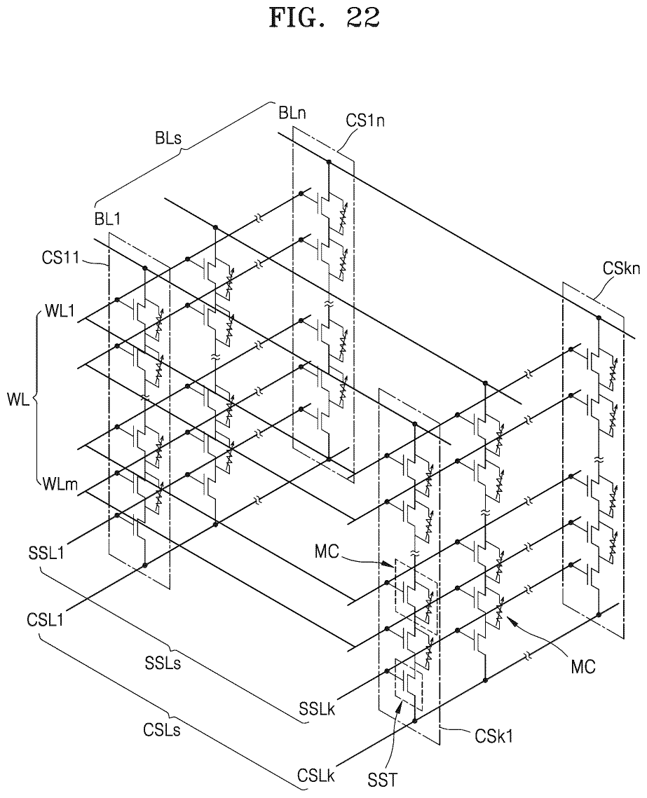

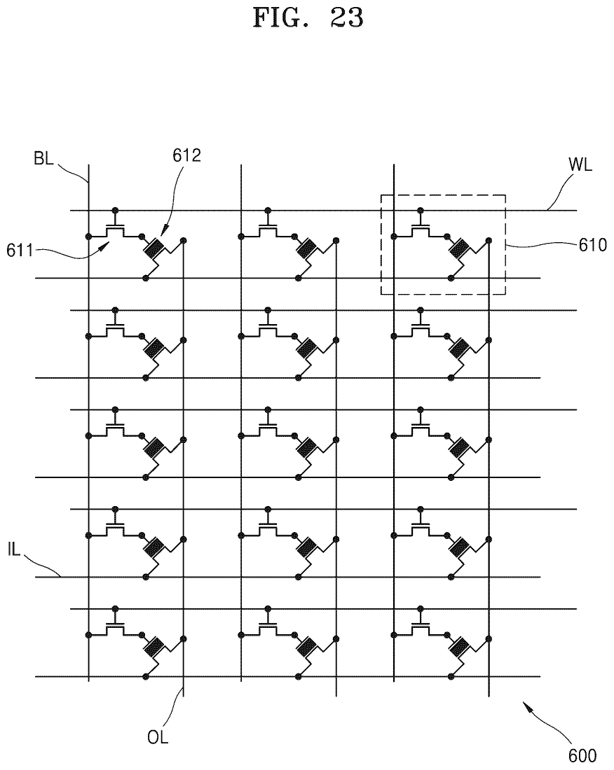

FIG. 22 is a diagram illustrating an equivalent circuit of a memory device according to at least one embodiment. Referring to FIG. 22, the memory device may include a plurality of memory cell strings CS11 to CSkn. The plurality of memory cell strings CS11 to CSkn may be two-dimensionally provided in a row direction and a column direction, thereby forming rows and columns. Each of the memory cell strings CS11 to CSkn may include a plurality of memory cells MC and a plurality of string selection transistors SST. The memory cells MC and the string selection transistors SST of each of the memory cell strings CS11 to CSkn may be stacked in a height direction. Each of the memory cells MC in each of the memory cell strings CS11 to CSkn may correspond to a circuit in which a transistor and an adjustable resistor are connected in parallel. For example, each of the memory cell strings CS11 to CSkn may be one of the memory cell strings 500, 500a, and 500b illustrated in FIGS. 18 to 21.

Rows of the plurality of memory cell strings CS11 to CSkn may be connected to a plurality of string selection lines SSL1 through SSLk, respectively. For example, the string selection transistors SST of the memory cell strings CS11 to CS In may be commonly connected to the string selection line SSL1. The string selection transistors SST of the memory cell strings CSkl to CSkn may be commonly connected to the string selection line SSLk.

In addition, columns of the plurality of memory cell strings CS11 to CSkn may be connected to the plurality of bit lines BLI through BLn, respectively. For example, the memory cells MC and the string selection transistors SST of the memory cell strings CS11 to CSkl may be commonly connected to the bit line BLI, and the memory cells MC and the string selection transistors SST of the memory cell strings CSIn to CSkn may be commonly connected to the bit line BLn.

In addition, the rows of the plurality of memory cell strings CS11 to CSkn may be connected to the plurality of common source lines CSL1 to CSLk, respectively. For example, the string selection transistors SST of the plurality of memory cell strings CS11 to CSIn may be commonly connected to the common source line CSL1, and the string selection transistors SST of the plurality of memory cell strings CSKI to CSkn may be commonly connected to the common source line CSLk.

The memory cells MC located at the same height from a substrate (or the string selection transistors SST) may be commonly connected to one word line WL, and the memory cells MC located at different heights from the substrate (or the string selection transistors SST) may be connected to the plurality of word lines WLI through WLm, respectively.

In such a structure, writing and reading may be performed in units of rows of memory cell strings CS11 to CSkn. For example, the memory cell strings CS11 to CSkn may be selected for each row by the common source lines CSL, and the memory cell strings CS11 to CSkn may be selected for each row by the string selection lines SSLs. In addition, the writing and reading operations may be performed for each page, in a selected row of the memory cell strings CS11 to CSkn. For example, the page may be one row of the memory cells MC connected to one word line WL. In the selected row of the memory cell strings CS11 to CSkn, the memory cells MC may be selected for each page by the word lines WL.

FIG. 23 is a schematic circuit diagram of a neural network device according to at least one embodiment. Referring to FIG. 23, a neural network device 600 according to at least one embodiment may include an array of a plurality of synapse devices 610 arranged in two dimensions. Each of the plurality of synapse devices 610 may include an access transistor 611 and a ferroelectric field effect transistor 612. The ferroelectric field effect transistor 612 may be any one of the ferroelectric field effect transistors described with reference to FIGS. 1 to 17 The access transistor 611 may serve as a selection element for turning on/off a respective one of the synapse devices 610.

The neural network device 600 may also include a plurality of word lines WL, a plurality of bit lines BL, a plurality of input lines IL, and a plurality of output lines OL. The gate of the access transistor 611 may be electrically connected to any one of the plurality of word lines WL, the source thereof may be electrically connected to any one of the plurality of bit lines BL, and the drain thereof may be connected to the gate of the ferroelectric field effect transistor 612. Further, the source of the ferroelectric field effect transistor 612 may be electrically connected to an input line of any one of the plurality of input lines IL, and a drain thereof may be electrically connected to an output line of any one of the plurality of output lines OL.

During the learning operation of the neural network device 600, the access transistor 611 is individually turned on through individual word lines WL, and a program pulse may be applied to the gate of the ferroelectric field effect transistor 612 through the bit lines BL. A signal of the training data may be applied through the input line IL. Through this process, weights may be stored in each ferroelectric field effect transistor 612.

During the inference operation of the neural network device 600, all access transistors 611 may be turned on through the entire word lines WL, and a read voltage Vread may be applied through the bit lines BL. Then, the current from synapse devices 610 connected in parallel to the output line OL is added to and flows in each output line OL. An output circuit is connected to the plurality of output lines OL to convert a current flowing through each output line OL into a digital signal.

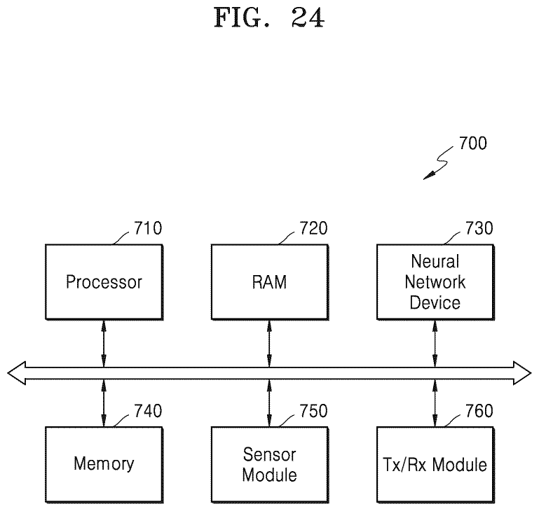

FIG. 24 is a schematic block diagram showing an example configuration of an electronic device including a neural network device. Referring to FIG. 24, the electronic device 700 may analyze input data in real time based on a neural network to extract valid information, determine a situation based on the extracted information, or control configurations of a device equipped with the electronic device 700. For example, the electronic device 700 may be applied to a robot device such as a drone, an advanced driver assistance system (ADAS), or the like, a smart TV, a smartphone, a medical device, a mobile device, an image display device, a measurement device, and an IoT device, and the like, and may be mounted on at least one of various types of devices.

The electronic device 700 may include a processor 710, a random access memory (RAM) 720, a neural network device 730, a memory 740, a sensor module 750, and a communication module 760. The electronic device 700 may further include an input/output module, a security module, a power control device, and the like. Some of the hardware components of the electronic device 700 may be mounted on at least one semiconductor chip.

The processor 710 controls the overall operation of the electronic device 700. The processor 710 may include a single processor core or a plurality of processor cores (i.e., Multi-Core). The processor 710 may process or execute programs and/or data stored in the memory 740. In some embodiments, the processor 710 may control the function of the neural network device 730 by executing programs stored in the memory 740. The processor 710 may be implemented as a central processing unit (CPU), a graphics processing unit (GPU), an application processor (ΔP), or the like.

The RAM 720 may temporarily store programs, data, or instructions. For example, programs and/or data stored in the memory 740 may be temporarily stored in the RAM 720 according to the control or boot code of the processor 710. The RAM 720 may be implemented as a memory such as dynamic RAM (DRAM), static RAM (SRAM), or the like.

The neural network device 730 may perform an operation of the neural network based on the received input data and generate an information signal based on the execution result. The neural network may include, but is not limited to, CNN, RNN, FNN, long short-term memory (LSTM), stacked neural network (SNN), state-space dynamic neural network (SSDNN), deep belief networks (DBN), restricted Boltzmann machine (RBM), and the like. The neural network device 730 may be a hardware accelerator itself dedicated to a neural network or a device including the same. The neural network device 730 may perform a read or write operation as well as an operation of the neural network. The neural network device 730 may correspond to the neural network device 600 according to the embodiment illustrated in FIG. 23.

The information signal may include one of various types of recognition signals such as a voice recognition signal, an object recognition signal, an image recognition signal, a biometric information recognition signal, and the like. For example, the neural network device 730 may receive frame data included in the video stream as input data and generate, from frame data, a recognition signal for an object included in an image represented by the frame data. However, the neural network device is not limited thereto, and the neural network device 730 may receive various types of input data and generate a recognition signal according to the input data according to the type or function of the device on which the electronic device 700 is mounted.

The neural network device 730 may perform, for example, machine learning model such as linear regression, logistic regression, statistical clustering, Bayesian classification, decision trees, principal component analysis, and/or expert system, and/or machine learning model of ensemble techniques, etc., such as random forest. The machine learning model may be used to provide various services such as, for example, image classification service, user authentication service based on biometric information or biometric data, advanced driver assistance system (ADAS), voice assistant service, automatic speech recognition (ASR) service, and the like.

The memory 740 is a storage place for storing data and may store an operating system (OS), various programs, and various pieces of data. In at least one embodiment, the memory 740 may store intermediate results generated during the operation of the neural network device 730.

The memory 740 may be a DRAM, but is not limited thereto. The memory 740 may include at least one of a volatile memory and a nonvolatile memory. The nonvolatile memory includes read-only memory (ROM), programmable ROM (PROM), electrically programmable ROM (EPROM), electrically erasable and programmable ROM (EEPROM), flash memory, phase-change ROM (PROM), magnetic ROM (MROM), resistive ROM (RROM), ferroelectric ROM (FROM), and the like. The volatile memory includes dynamic RAM (DRAM), static RAM (SRAM), synchronous DRAM (SDRAM), phase-change RAM (PRAM), magnetic RAM (MRAM), resistive RAM (RRAM), ferroelectric RAM (FeRAM), and/or the like. In at least one embodiment, the memory 740 may include at least one of a hard disk drive (HDD), a solid-state drive (SSD), a compact flash (CF), a secure digital (SD), a micro secure digital (Micro-SD), a mini secure digital (Mini-SD), a memory stick, and/or the like.

The sensor module 750 may collect information around a device on which the electronic device 700 is mounted. The sensor module 750 may sense or receive a signal (e.g., an image signal, a voice signal, a magnetic signal, a bio signal, a touch signal, etc.) from the outside of the electronic device 700 and convert the sensed or received signal into data. To this end, the sensor module 750 may include at least one of various types of sensing devices such as a sensing device, for example, a microphone, an imaging device, an image sensor, a light detection and ranging (LIDAR) sensor, an ultrasonic sensor, an infrared sensor, a biosensor, and a touch sensor.

The sensor module 750 may provide the converted data to the neural network device 730 as input data. For example, the sensor module 750 may include an image sensor, generate a video stream by photographing an external environment of the electronic device 700, and sequentially provide the continuous data frame of the video stream to the neural network device 730 as input data. However, embodiments are not limited thereto, and the sensor module 750 may provide various types of data to the neural network device 730.

The communication module 760 may include various wired or wireless interfaces capable of communicating with an external device. For example, the communication module 760 may include a wired local area network (LAN), a wireless local area network (WLAN) such as a wireless fidelity (Wi-Fi), a wireless personal area network (WPAN) such as Bluetooth, a wireless universal serial bus (USB), Zigbee, near field communication (NFC), radio-frequency identification (RFID), power line communication (PLC), and a communication interface capable of connecting to a mobile cellular network, such as 3rd generation (3G), 4th generation (4G), long term evolution (LTE), and the like.

The ferroelectric field effect transistor, the memory device, and the neural network device described above have been described with reference to the embodiments shown in the drawings, which are only nonlimiting examples.

it should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A ferroelectric field effect transistor comprising:
a channel layer including an oxide semiconductor material;
a source electrode and a drain electrode electrically connected to the channel layer,
a gate electrode facing and spaced apart from the channel layer;
a ferroelectric layer between the channel layer and the gate electrode, the ferroelectric layer including a ferroelectric material; and
an intermediate oxide layer between the channel and the ferroelectric layer the intermediate oxide layer comprising an oxide material of a metal element having oxide formation energy greater than oxide formation energy of a metal element of the ferroelectric material of the ferroelectric layer and less than oxide formation energy of a metal element of the oxide semiconductor material of the channel layer.

2. The ferroelectric field effect transistor of claim 1, wherein the intermediate oxide layer comprises an oxide material having a dielectric constant of 20 or more.

3. The ferroelectric field effect transistor of claim 1, wherein
the ferroelectric material of the ferroelectric layer comprises hafnium oxide, and
the oxide semiconductor material of the channel layer comprises an oxide of at least one of indium (In), gallium (Ga), zinc (Zn), tungsten (W), or tin (Sn).

4. The ferroelectric field effect transistor of claim 3, wherein the intermediate oxide layer comprises at least one of niobium oxide (Nb₂O₅₋ₓ), tantalum oxide (Ta₂O₅₋ₓ), or titanium oxide (TiO₂₋ₓ), and
the at least one of niobium oxide (Nb₂O₅₋ₓ), tantalum oxide (Ta₂O₅₋ₓ), or titanium oxide (TiO₂₋ₓ) has a stoichiometrically oxygen-deficient composition, where x is greater than 0 and less than or equal to 0.5.

5. The ferroelectric field effect transistor of claim 1, wherein a thickness of the intermediate oxide layer is less than a thickness of the channel layer.

6. The ferroelectric field effect transistor of claim 1, wherein
a thickness of the channel layer is about 5 nanometers (nm) to about 20 nm, and
a thickness of the intermediate oxide layer is about 0.1 nm to about 2 nm.

7. The ferroelectric field effect transistor of claim 1, further comprising:
a gate intermediate layer between the gate electrode and the ferroelectric layer, the gate intermediate layer comprising at least one amorphous dielectric material from among silicon oxide, silicon nitride, aluminum oxide, or silicon oxynitride.

8. The ferroelectric field effect transistor of claim 7, wherein
the gate intermediate layer comprises the amorphous silicon oxynitride,
the gate intermediate layer comprises a first surface adjacent to the gate electrode and a second surface adjacent to the ferroelectric layer,
a nitrogen concentration in the gate intermediate layer gradually increases from the first surface toward the second surface. and
an oxygen concentration in the gate intermediate layer gradually decreases from the first surface toward the second surface.

9. The ferroelectric field effect transistor of claim 8, wherein
the oxygen concentration at the first surface of the gate intermediate layer is greater by a ratio of 10% or more compared to the oxygen concentration at the second surface of the gate intermediate layer, and
a nitrogen concentration at the second surface of the gate intermediate layer is greater by a ratio of 10% or more compared to a nitrogen concentration at the first surface of the gate intermediate layer.

10. The ferroelectric field effect transistor of claim 8, wherein
a silicon concentration in the gate intermediate layer gradually increases from the first surface toward the second surface, and
a silicon concentration at the second surface of the gate intermediate layer is greater by a ratio of 10% or more compared to a silicon concentration at the first surface of the gate intermediate layer.

11. The ferroelectric field effect transistor of claim 10, wherein a ratio of the silicon concentration to the nitrogen concentration on the first surface of the gate intermediate layer and a ratio of the silicon concentration to the nitrogen concentration on the second surface of the gate intermediate layer are the same.

12. The ferroelectric field effect transistor of claim 7, wherein
the gate intermediate layer comprises a first gate intermediate layer adjacent to the ferroelectric layer and a second gate intermediate layer adjacent to the gate electrode,
the first gate intermediate layer comprises at least one of amorphous silicon nitride or amorphous silicon oxynitride, and
the second gate intermediate layer comprises amorphous silicon oxide.

13. The ferroelectric field effect transistor of claim 12, wherein
the first gate intermediate layer comprises the amorphous silicon oxynitride,
the first gate intermediate layer comprises a first surface adjacent to the gate electrode and a second surface adjacent to the ferroelectric layer, and
a nitrogen concentration in the first gate intermediate layer gradually increases from the first surface toward the second surface, and
an oxygen concentration in the first gate intermediate layer gradually decreases from the first surface toward the second surface.

14. The ferroelectric field effect transistor of claim 13, wherein
a silicon concentration in the first gate intermediate layer gradually increases from the first surface toward the second surface, and
a ratio of the silicon concentration to the nitrogen concentration on the first surface of the first gate intermediate layer and a ratio of the silicon concentration to the nitrogen concentration on the second surface of the first gate intermediate layer are the same.

15. The ferroelectric field effect transistor of claim 1, wherein
the channel layer comprises a first surface and a second surface facing each other, and
the source electrode and the drain electrode are spaced apart from each other on the first surface of the channel layer, and the gate electrode faces the second surface of the channel layer such that the channel layer is between the gate electrode and the source and drain electrodes.

16. The ferroelectric field effect transistor of claim 1, wherein
the channel layer comprises a first surface and a second surface facing each other, and
the gate electrode is provided to face the first surface of the channel layer,
the source electrode and the drain electrode are spaced apart from each other on the first surface of the channel layer,
the intermediate oxide layer is provided between the source electrode and the drain electrode on the first surface of the channel layer,
the source electrode faces a first side surface of the intermediate oxide layer, and the drain electrode faces a second side surface of the intermediate oxide layer opposite to the first side surface.

17. The ferroelectric field effect transistor of claim 1, wherein
the channel layer, the intermediate oxide layer, the ferroelectric layer, and the gate electrode extend in a first direction and are sequentially arranged in a second direction perpendicular to the first direction, and
the source electrode and the drain electrode are electrically connected to respective ends of the channel layer in the first direction.

18. The ferroelectric field effect transistor of claim 17, wherein
the channel layer has a cylindrical shape,
the intermediate oxide layer surrounds the channel layer,
the ferroelectric layer surrounds the intermediate oxide layer, and
the gate electrode surrounds the ferroelectric layer.

19. A memory device comprising:
a plurality of gate electrodes and a plurality of spacers alternately stacked in a first direction;
a channel layer spaced apart from the plurality of gate electrodes and the plurality of spacers in a second direction perpendicular to the first direction, the channel layer extending in the first direction and comprising an oxide semiconductor material;
a ferroelectric layer between the channel layer and the plurality of gate electrodes and extending in the first direction, the ferroelectric layer including a ferroelectric material; and
an intermediate oxide layer between the ferroelectric layer and the channel layer and extending in the first direction such that the intermediate oxide layer separates the ferroelectric layer from the channel layer, the intermediate oxide layer comprising an oxide material of a metal element having oxide formation energy greater than oxide formation energy of a metal element of the ferroelectric material of the ferroelectric layer and less than oxide formation energy of a metal element of the oxide semiconductor material of the channel layer.

20. A neural network device comprising:
an array of a plurality of synapse devices, each of the plurality of synapse devices comprising an access transistor and a ferroelectric field effect transistor,
wherein the ferroelectric field effect transistor comprises
a channel layer comprising an oxide semiconductor material,
a source electrode and a drain electrode electrically connected to the channel layer,
a gate electrode facing and spaced apart from the channel layer,
a ferroelectric layer between the channel layer and the gate electrode, the ferroelectric layer including a ferroelectric material, and
an intermediate oxide layer between the channel and the ferroelectric layer, the intermediate oxide layer comprising an oxide material of a metal element having oxide formation energy greater than oxide formation energy of a metal element of the ferroelectric material of the ferroelectric layer and less than oxide formation energy of a metal element of the oxide semiconductor material of the channel layer.
